(19) United States
(12) Patent Application Publication
(10) Pub. No.: US 2005/0142885 A1
(43) Pub. Date: Jun. 30, 2005

(54) Method of etching and etching apparatus

(75) Inventor: Hiroshi Shinriki, Nirasaki-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/066,268

(22) Filed: Feb. 28, 2005

Related U.S. Application Data
(63) Continuation of application No. PCT/JP03/10505, filed on Aug. 20, 2003.

(30) Foreign Application Priority Data
Aug. 30, 2002 (JP) 2002-252274

(51) Int. Cl. B08B 3/00; H01L 21/4763; H01L 21/302; H01L 21/461

(52) U.S. Cl. 438/706; 438/623; 134/44

(57) ABSTRACT

A thin film formed on a substrate is etched, without generating a plasma, with an etching gas containing a β-diketone and a gas containing water and/or alcohol, thereby exposing a surface of the substrate.

This application is a Continuation Application of PCT International Application No. PCT/JP2003/010505 filed on Aug. 20, 2003, which designated the United States.

### FIELD OF THE INVENTION

The present invention relates to an etching method and an etching apparatus.

### BACKGROUND OF THE INVENTION

Recently, it has become an important industrial task to develop a gate insulating film, which is capable of reducing a gate operating voltage of a MOS (metal-oxide-semiconductor) transistor while, at the same time, providing an excellent withstand voltage. To achieve this goal, attention has been paid to the formation of a gate insulating film with a high-k dielectric insulating film such as a HfO₂ film.

However, the use of a high-k dielectric insulating film as a gate insulating film tends to entail a reduction in a drain current during an operation of the MOS transistor. Since the decreased drain current may adversely affect the speed of a device, it is preferable that such reduction in the drain current be avoided. For such purpose, therefore, placement of a Si-containing film, such as a SiON film, between the high-k dielectric insulating film and a Si substrate has been proposed.

On the other hand, the high-k dielectric insulating film and the Si-containing film formed on the Si substrate need to be etched so as to shape them into a desired form. Under the present situation, a HF solution is used to etch both the high-k dielectric insulating film and the Si-containing film.

However, if the high-k dielectric insulating film and the Si-containing film are etched with a HF solution, a field oxide film placed beneath the Si-containing film may be partially damaged, which can be problematic.

### SUMMARY OF THE INVENTION

It is, therefore, an object of the present invention to provide an etching method and an etching apparatus for reducing damages to a substrate.

In accordance with one aspect of the present invention, there is provided an etching method, comprising the steps of: providing a substrate with a thin film formed thereon; and etching, without generating a plasma, the thin film formed on the substrate with an etching gas containing a β-diketone and a gas containing water and/or alcohol to expose a surface of the substrate. Since the etching method of the present invention is provided with the inventive etching step, damages to the substrate can be suppressed. Further, the etching rate can be increased by using the gas containing water and/or alcohol.

Further, a preferred β-diketone that can be used in the present invention is hexafluoro acetyl acetone (Hhfac). By using said Hhfac, damages to the substrate can be reduced effectively.

Furthermore, it is preferable that the etching gas containing a β-diketone includes the gas containing water and/or alcohol. Specifically, by mixing a gas containing water and/or alcohol with the etching gas containing a β-diketone, the etching rate can be improved.

Further, the etching may be conducted by alternating the supply of an etching gas containing a β-diketone and that of a gas containing water and/or alcohol. The alternate supplying of the gases makes the etching performed in a more accurate fashion.

It is also preferable that the etching be conducted while maintaining the substrate at a temperature of 300° C. or higher, preferably, 450° C. or higher. The etching rate can be improved if the etching is performed under such condition.

Further, it is preferable that the etching gas containing a β-diketone be supplied in such a manner that it flows along a surface of the thin film. The etching rate can be improved with such supply of the etching gas containing a β-diketone.

It is preferable that the thin film include a metal film and/or a metal oxide film. The etching gas containing a β-diketone is useful in etching the metal film and/or the metal oxide film.

Further, it is preferable that the metal film and/or the metal oxide film include at least one element selected from the group consisting of Al, Zr, Hf, Y, La, Ce and Pr. When the metal film and/or the metal oxide film includes such element(s), damages to the substrate can be mitigated effectively.

Further, it is preferable that a surface of the substrate be made of a Si-containing film. By constructing the substrate to be covered with the Si-containing film, the etching of the thin film can be made to stop upon the exposure of the Si-containing film.

The etching method may further comprise the step of etching the Si-containing film. It is preferable that the Si-containing film is etched with an etching gas including a fluorine-containing gas or with an etching solution including a hydrogen fluoride solution. When the Si-containing film is etched as described above, the etching rate of the Si-containing film can be improved.

It is preferable that the etching gas including the fluorine-containing gas contains water and/or alcohol. If the etching gas including the fluorine-containing gas is provided with such component(s), the etching rate of the Si-containing film can be improved further.

Further, the etching of the Si-containing film may be conducted by alternating the supply of an etching gas including a fluorine-containing gas and that of a gas including water and/or alcohol. The etching of the Si-containing film can be done in a more accurate fashion with such alternate supply.

Furthermore, it is preferable that the etching of the Si-containing film be conducted while maintaining the substrate at a temperature of 100° C. or less. The etching rate of the Si-containing film is improved when the etching is conducted under such condition.

In accordance with another aspect of the present invention, there is provided an etching apparatus, comprising: a reactor for accommodating a substrate on which a first thin film and a second thin film are formed, the second thin film being disposed under the first thin film; a first supply system for feeding a first etching gas containing a β-diketone into the reactor to etch the first thin film; and a second supply system for feeding a second etching gas including a fluorine-containing gas, or an etching solution including a hydrogen fluoride solution into the reactor to etch the second thin film. Since the etching apparatus of the present invention is provided with the first supply system for feeding the etching gas containing a β-diketone, damages to the substrate can be reduced. Further, the first and second thin films can be etched in a continuous manner. In addition, the first and second thin films can be etched in a single etching apparatus.

In accordance with a further aspect of the present invention, there is provided an etching apparatus comprising: a first reactor for accommodating a substrate on which a first thin film and a second thin film are formed, the second thin film being disposed under the first thin film; a first supply system for feeding a first etching gas containing a β-diketone into the first reactor to etch the first thin film; a second reactor for accommodating the substrate after the first thin film is removed by etching; a second supply system for feeding a second etching gas including a fluorine-containing gas, or an etching solution including a hydrogen fluoride solution into the second reactor to etch the second thin film; and a substrate transfer system for transferring the substrate into the first and the second reactors. Since the etching apparatus of the present invention is provided with the first supply system for feeding the etching gas containing a β-diketone, damages to the substrate can be mitigated. Further, the first and second thin films can be etched in a continuous manner.

Furthermore, a preferred β-diketone that can be used in the present invention is Hhfac. By using Hhfac as the β-diketone, damages to the substrate can be effectively mitigated.

### BRIEF DESCRIPTION OF THE DRAWINGS

The above and other objects and features of the present invention will become apparent from the following description of preferred embodiments given in conjunction with the accompanying drawings, in which:

FIG. 1 shows a schematic vertical sectional view of an etching apparatus in accordance with a first preferred embodiment of the present invention;

FIG. 2 describes a schematic top sectional view of the etching apparatus in accordance with the first preferred embodiment;

FIG. 3 illustrates a schematic view of a wafer before it is etched in accordance with the first preferred embodiment;

FIG. 4 offers a flow chart showing the steps of etching executed in the etching apparatus in accordance with the first preferred embodiment;

FIG. 5 delineates a schematic view of the etching performed in accordance with the first preferred embodiment;

FIG. 6. outlines a schematic view of the etching performed in accordance with the first preferred embodiment;

FIG. 7A exhibits a schematic view of a chemical structure of Hhfac used in the first preferred embodiment, and FIG. 7B shows a schematic view of a chemical structure formula of Hf complex generated in the first preferred embodiment;

FIG. 8A discloses a schematic view of a wafer after a HfO₂ film is removed by etching in accordance with the first preferred embodiment, and FIG. 8B shows a schematic view of a wafer after a SiON film is removed by etching in accordance with the first preferred embodiment;

FIG. 9 reveals relationships between a wafer temperature and an etching rate of a HfO₂ film based on the results obtained in Example 2 and Reference Example 2;

FIG. 10 provides relationships between a wafer temperature and an etching rate of an Al₂O₃ film based on the results obtained in Example 3 and Reference Example 3;

FIG. 11 records relationships between a pressure in an inner chamber and an etching rate of a HfO₂ film based on the results obtained in Example 4 and Reference Example 4;

FIG. 12 presents a relationship between a Hhfac flow rate and an etching rate based on the result obtained in Example 5;

FIG. 13 indicates relationships between an O₂ flow rate and an etching rate of a HfO₂ film based on the results obtained in Example 6 and Reference Example 6;

FIG. 14 demonstrates relationships between an O₂ flow rate and an etching rate of an Al₂O₃ film based on the results obtained in Example 7 and Reference Example 7;

FIG. 15 represents relationships between a concentration of H₂O and an etching rate of a HfO₂ film based on the results obtained in Example 8 and Reference Example 8;

FIG. 16 accords relationships between a H₂O concentration and an etching rate of an Al₂O₃ film based on the results obtained in Example 9 and Reference Example 9;

FIG. 17 introduces a relationship between a concentration of C₂H₅OH and an etching rate based on the result obtained in Example 10;

FIGS. 18A and 18B visualize flow charts describing the steps of etching executed in the etching apparatus in accordance with a second preferred embodiment;

FIG. 19 relates to a schematic vertical sectional view of an etching apparatus in accordance with a third preferred embodiment;

FIG. 20 expresses a flow chart showing the steps of etching executed in the etching apparatus in accordance with the third preferred embodiment;

FIG. 21 reproduces a schematic diagram of the etching performed in accordance with the third preferred embodiment;

FIG. 22 exemplifies a schematic vertical sectional view of an etching apparatus in accordance with a fourth preferred embodiment;

FIG. 23 charts a schematic view of an etching apparatus in accordance with a fifth preferred embodiment;

FIG. 24 sets forth a schematic vertical sectional view of a first etching part in the fifth preferred embodiment;

FIG. 25 gives a schematic vertical sectional view of a second etching part in the fifth preferred embodiment; and

FIGS. 26A and 26B yield flow charts showing the steps of etching executed in the etching apparatus in accordance with the fifth preferred embodiment.

### DETAILED DESCRIPTION OF THE PREFERRED EMBODIMENTS

### First Preferred Embodiment

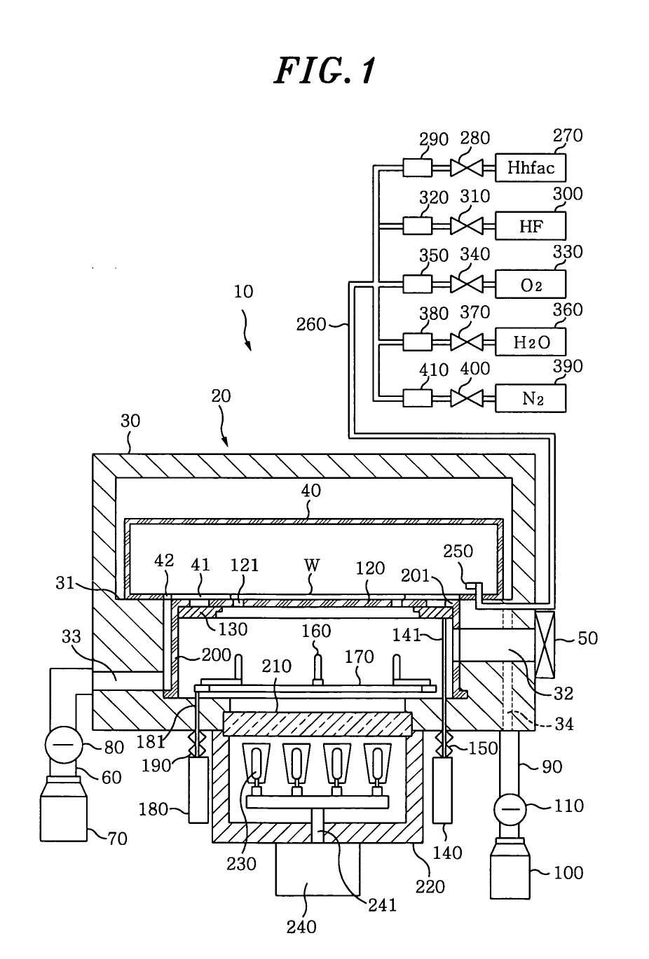

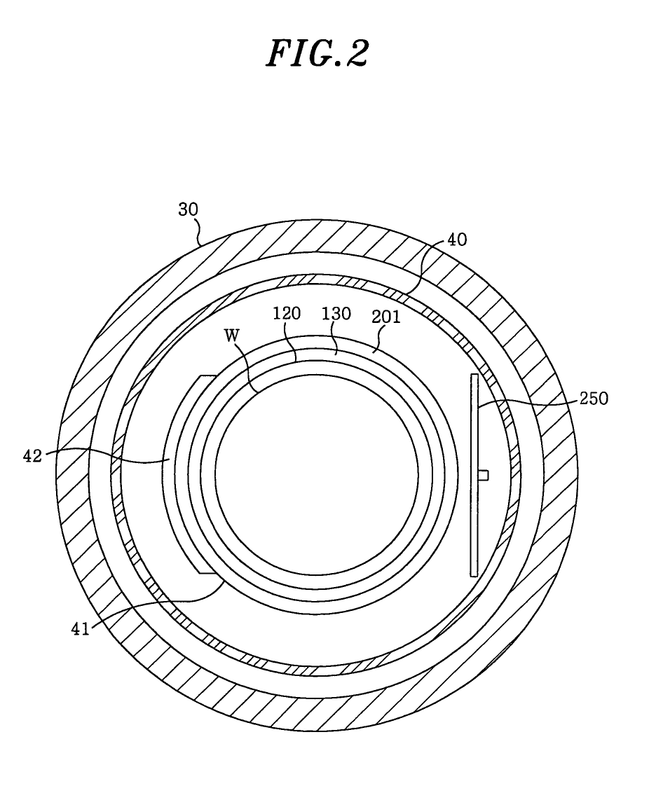

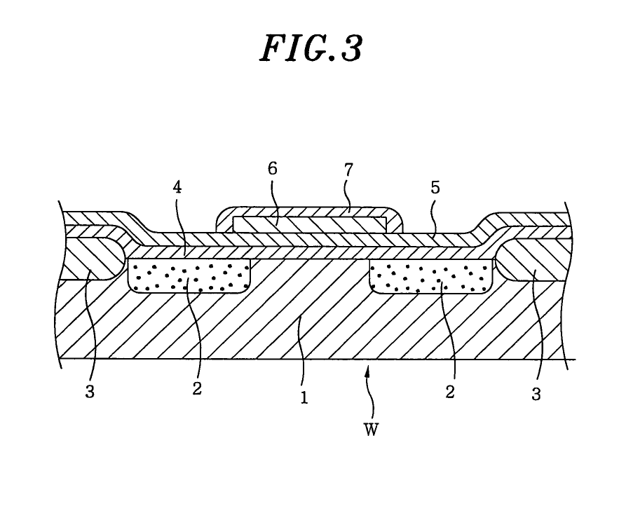

Hereinafter, a description will be given of an etching apparatus in accordance with a first preferred embodiment of the present invention. FIG. 1 schematically illustrates a vertical sectional view of the etching apparatus in accordance with the first preferred embodiment. FIG. 2 shows a top sectional view thereof; and FIG. 3 schematically illustrates a wafer before it is etched in accordance with the first preferred embodiment.

As shown in FIGS. 1 and 2, the etching apparatus 10 is equipped with a chamber 20 for housing a semiconductor wafer W. The chamber 20 includes an outer chamber 30 and an inner chamber 40, the inner chamber 40 being placed inside the outer chamber 30.

The outer chamber 30 is made of, e.g., Al. However, it can be made of hastelloy or the like and is not limited to Al in its construction. In addition, an inside wall of the outer chamber 30 may be subject to a surface treatment such as an alumite treatment or a PTFE (polytetrafluoroethylene) coating. A ledge 31 is formed on an inside wall of the outer chamber 30 to protrude inward. Openings 32, 33, 34 are provided as well at certain positions of the outer chamber 30.

A gate valve 50 is installed at an outer end of the opening 32 for the purpose of separating the outer chamber 30 from the exterior environment. One end of a gas exhaust line 60 is connected to the opening 33 at an outer end thereof to exhaust the inner chamber 40. The other end of the gas exhaust line 60 is connected to a depressurization pump 70. The inner chamber 40 can be exhausted through the opening 33 by an operation of the depressurization pump 70. An automatic pressure controller 80 is installed at the gas exhaust line 60 to control the pressure of the inner chamber 40. The pressure of the inner chamber 40 can be adjusted at a desired level by changing a conductance of the automatic pressure controller 80.

In addition, one end of a gas exhaust line 90 is connected to the opening 34 at an outer end thereof to exhaust a space formed between the outer chamber 30 and the inner chamber 40. The other end of the gas exhaust line 90 is connected to a depressurization pump 100. The space formed between the outer chamber 30 and the inner chamber 40 can be exhausted through the opening 34 by an operation of the depressurization pump 100, thereby preventing a heat transfer between the inner chamber 40 and the outer chamber 30. An automatic pressure controller 110 is installed at the gas exhaust line 90 to control the pressure in the space formed between the outer chamber 30 and the inner chamber 40. The pressure in the space formed between the outer chamber 30 and the inner chamber 40 can be adjusted at a desired level by controlling a conductance of the automatic pressure controller 110.

Further, a disk-shaped susceptor 120 is provided in the outer chamber 30 for loading a wafer W thereon. The susceptor 120 is made of, e.g., ceramics such as AlN or Al₂O₃. A further description will now be given for the wafer W which is to be loaded on the susceptor 120.

As shown in FIG. 3, the wafer W has a P-type Si substrate 1, a part of the P-type Si substrate 1 being covered with a N-type diffusion layer 2. It must be noted that the substrate 1 is not limited to a P-type Si substrate but can be a N-type Si substrate instead. A SiO₂ film 3 may be formed on the substrate 1 to function as a field oxide layer, and may have a thickness of about 1000 Å.

Further, a SiON film 4 and a HfO₂ film 5 are formed on the P-type Si substrate 1 and the SiO₂ film 3 as gate insulating films. Specifically, the HfO₂ film 5 is placed above the SiON film 4. The SiON film 4 has a thickness of about 10 Å or less and the HfO₂ film 5 is formed at a thickness of about 20-40 Å. Other Si-containing films may be employed in place of the SiON film 4. A SiO₂ film and a SiN film exemplify such Si-containing film. Further, other high-k dielectric insulating films may be used in place of the HfO₂ film 5. Examples of such high-k dielectric insulating film include a metal oxide film such as an Al₂O₃ film, a ZrO₂ film, a La₂O₃ film, a Y₂O₃ film, a CeO₂ film, a Ce₂O₃ film, a Pr₂O₃ film, a Pr₆₀₁₁ film or a PrO₂ film.

On the HfO₂ film 5, a patterned W film 6 is formed to function as a gate electrode. A metal film or a polysilicon film may be used in place of the W film 6. Examples of the metal film include a Ti film, a Mo film and a Ta film. A SiO₂ film 7 is coated over the W film 6 to work as a sidewall. Other Si-containing films can be employed as well as a sidewall, in place of SiO₂. For instance, Si-containing film such as a Si₃N₄ film can be used instead.

Three holes 121 are formed and penetrate through the susceptor 120 to help the loading/unloading of the wafer W.

The susceptor 120 is supported by, e.g., a ring-shaped supporting member 130 made of ceramics. An air cylinder 140 is connected to the supporting member 130. The susceptor 120 moves upward and downward by the vertical movement of a rod 141, the movement being triggered by the operation of the air cylinder 140. The susceptor 120 stops at two positions: a transfer position for transferring the wafer W; and an etching position for etching the wafer W.

Further, the rod 141 is covered with a bellows 150 at an outside of the outer chamber 30. By covering the rod 141 with the bellows 150 having stretchy properties (i.e., expanding and contracting freely), an air-tightness in the outer chamber 30 can be maintained.

Wafer elevating pins 160 are provided under the holes 121 of the susceptor 120 to be inserted thereinto. The wafer elevating pins 160 are fixed perpendicularly to a ring-shaped support 170.

Further, the support 170 for elevating pins is provided with an air cylinder 180. When a rod 181 in the air cylinder 180 moves downward, the wafer elevating pins 160 are pulled out of the holes 121 and the wafer W (which was supported by the wafer elevating pins 160) is placed on the susceptor 120 to be loaded thereon. Conversely, when the rod 181 of the air cylinder 180 moves upwards, the wafer elevating pins 160 are inserted into the holes 121, thereby unloading the wafer W (which was loaded on the susceptor 120) therefrom.

The rod 181 is covered with a bellows 190 at an outside of the outer chamber 30, by which the air tightness of the outer chamber 30 is maintained.

A cylindrically shaped member 200 is disposed to surround the susceptor 120 and the supporting member 130. The cylindrically shaped member 200 is made of, e.g., quartz. At an upper part of the cylindrically shaped member 200, a flange 201 is formed to protrude inward. An internal diameter of the formed flange 201 is set to be smaller than an outer diameter of the supporting member 130 but is large enough to receive the susceptor 120. As such, the susceptor 120 is stopped at the etching position by the flange 201. Also, there is provided a space between the cylindrically shaped member 200 and the outer chamber 30 for communication with the opening 33.

A heat-ray penetration window 210 made of, e.g., quartz is provided under the susceptor 120 to allow heat radiation passing through it. The heat-ray penetration window 210 is fitted into the outer chamber 30 to be fixed therein. A heating chamber 220 is disposed under the heat-ray penetration window 210 to enclose it.

Further, heating lamps 230 are provided in the heating chamber 220 for the purpose of heating the susceptor 120. Once the heating lamps 230 are turned on, the heat-rays radiating therefrom pass through the heat-ray penetration window 210 to heat the susceptor 120, which is disposed above the heat-ray penetration window 210. Heating means in the heating chamber 220 can be other heating devices such as a resistance-heating unit and is not limited to the heating lamps 230.

In addition, a motor 240 is connected to the heating lamps 230 so as to rotate the heating lamps 230. The motor 240 spins a rotating shaft 241 to turn around the heating lamps 230, thereby entailing a uniform application of heat to the wafer W.

The inner chamber 40 is placed on the ledge 31 of the outer chamber 30. The inner chamber is made of, e.g., quartz. An opening 41 for receiving the wafer W and an exhaust port 42 for exhausting the inner chamber 40 are formed at the bottom of the inner chamber 40. The exhaust port 42 is located so that it is in communication with the space formed between the outer chamber 30 and the cylindrically shaped member 200. By placing an exhaust port like this, the inner chamber 40 can be exhausted when the depressurization pump 70 operates.

A nozzle 250 is provided in the inner chamber 40 to supply a Hhfac-containing etching gas into the inner chamber 40. The nozzle 250 is placed in a direction to face the exhaust port 42 and the wafer W is disposed therebetween. As the nozzle 250 is close to the bottom of the inner chamber 40, the Hhfac-containing etching gas flows along a surface of the wafer W. The nozzle 250 is connected to a gas supply line 260 which has a five-forked end.

A first end of the gas supply line 260 is connected to a Hhfac supply source 270 having hexafluoro acetyl acetone (CF₃COCH₂COCF₃: Hhfac) therein. The supply source 270 is not limited to Hhfac but other β-diketone may be employed as well such as tetramethyl heptanedion ((CH₃)₃CCOCH₂COC(CH₃)₃: Hthd) or acetyl acetone (CH₃COCH₂COCH₃). An opening/closing valve 280 and a mass flow controller 290 for controlling a Hhfac flow rate are provided at the gas supply line 260 to regulate the feeding of Hhfac. By adjusting the mass flow controller 290, the Hhfac flow rate can be controlled at a desired level when the valve 280 is opened and Hhfac in the supply source 270 is released into the inner chamber 40.

A second end of the gas supply line 260 is connected to a HF supply source 300 containing absolute HF. An opening/closing valve 310 and a mass flow controller 320 for controlling a HF flow rate are provided at the gas supply line 260 to regulate the feeding of HF. By adjusting the mass flow controller 320, the HF flow rate can be controlled at a desired level when the valve 310 is opened and HF in the supply source 300 is released into the inner chamber 40.

A third end of the gas supply line 260 is connected to an O₂ supply source 330 containing O₂. An opening/closing valve 340 and a mass flow controller 350 for controlling an O₂ flow rate are provided at the gas supply line 260 to regulate the feeding of O₂. By adjusting the mass flow controller 350, the O₂ flow rate can be controlled at a desired level when the valve 340 is opened and O₂ in the supply source 330 is released into the inner chamber 40.

A fourth end of the gas supply line 260 is connected to a H₂O supply source 360 containing H₂O. Alcohol such as ethanol (C₂H₅OH) may also be used in place of H₂O. An opening/closing valve 370 and a mass flow controller 380 for controlling a flow rate of H₂O are provided at the gas supply line 260 to regulate the feeding of H₂O. By adjusting the mass flow controller 380, the H₂O flow rate can be controlled at a desired level when the valve 370 is opened and H₂O in the supply source 360 is released into the inner chamber 40.

A fifth end of the gas supply line 260 is connected to a N₂ supply source 390 containing N₂. An opening/closing valve 400 and a mass flow controller 410 for controlling a flow rate of N₂ are provided at the gas supply line 260 to regulate the feeding of N₂. By adjusting the mass flow controller 410, N₂ flow rate can be controlled at a desired level when the valve 400 is opened and N₂ in the supply source 390 is released into the inner chamber 40.

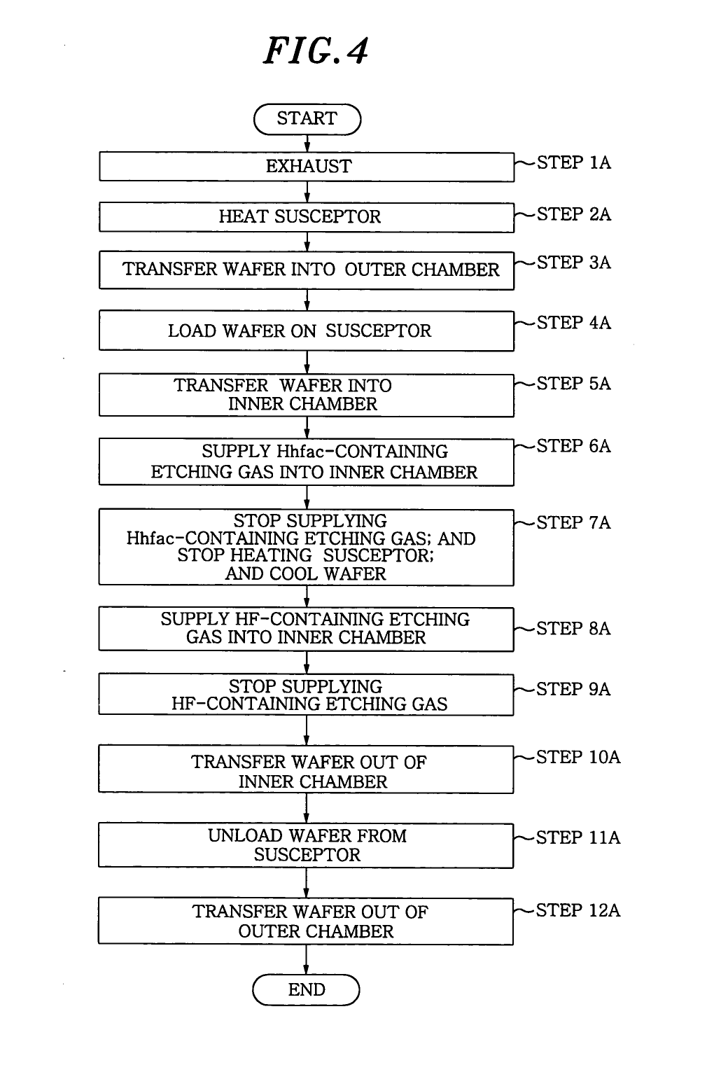

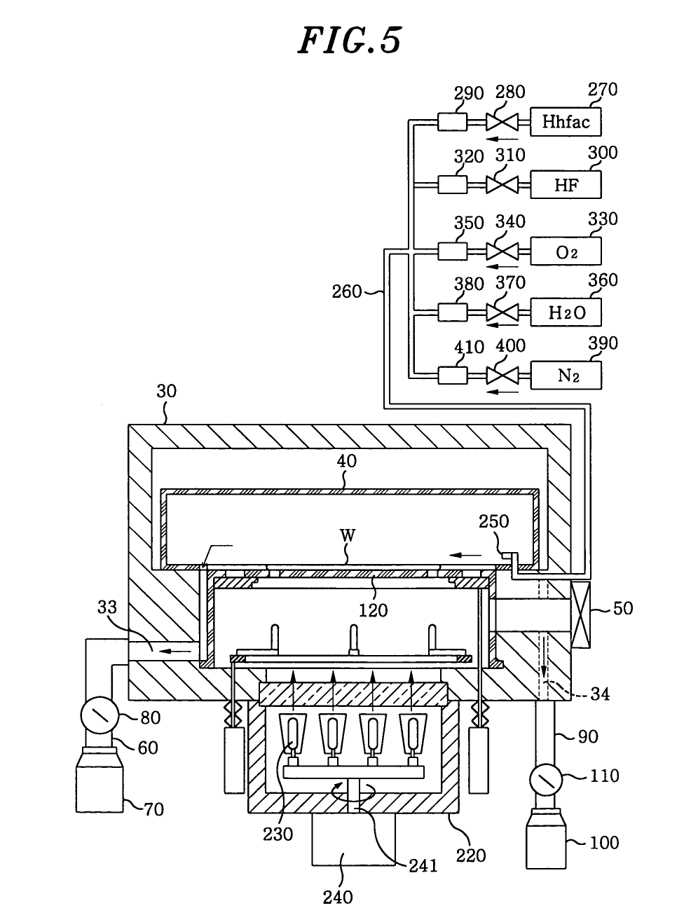

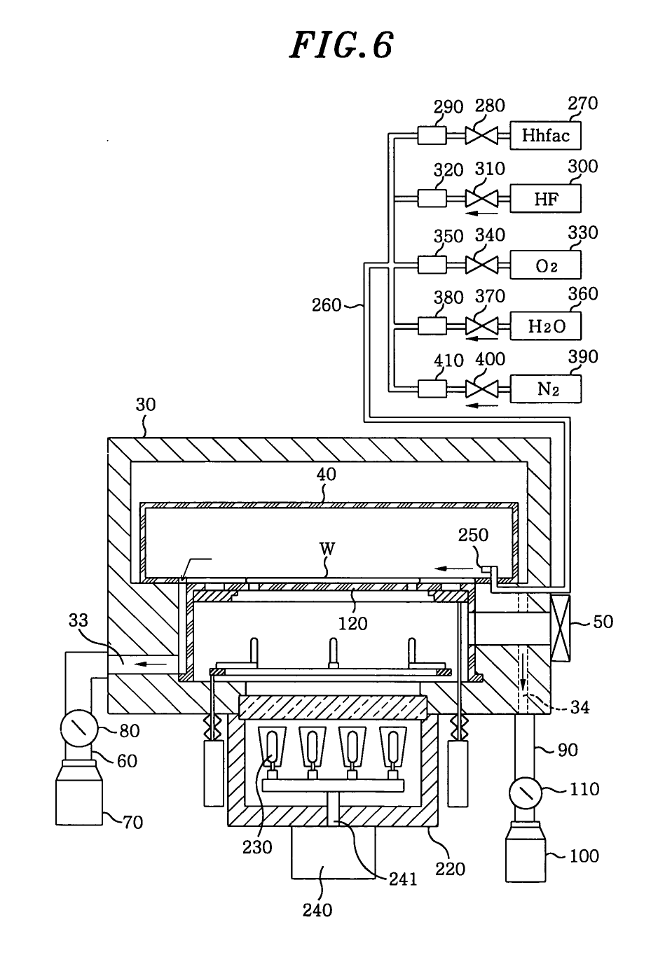

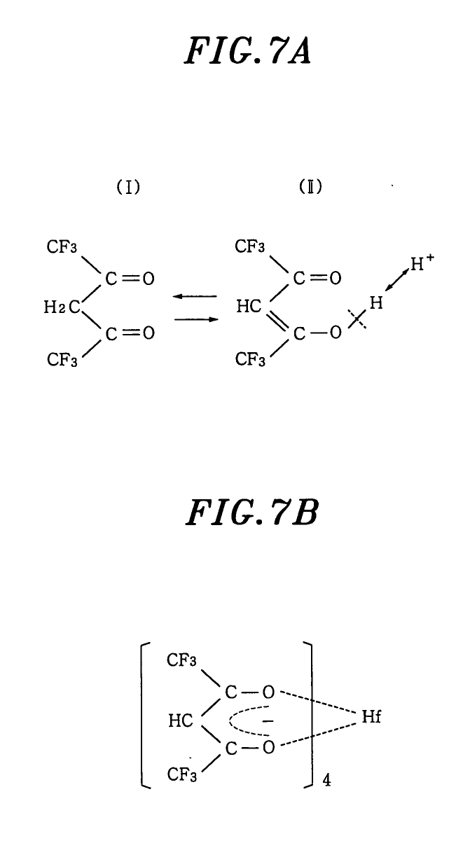

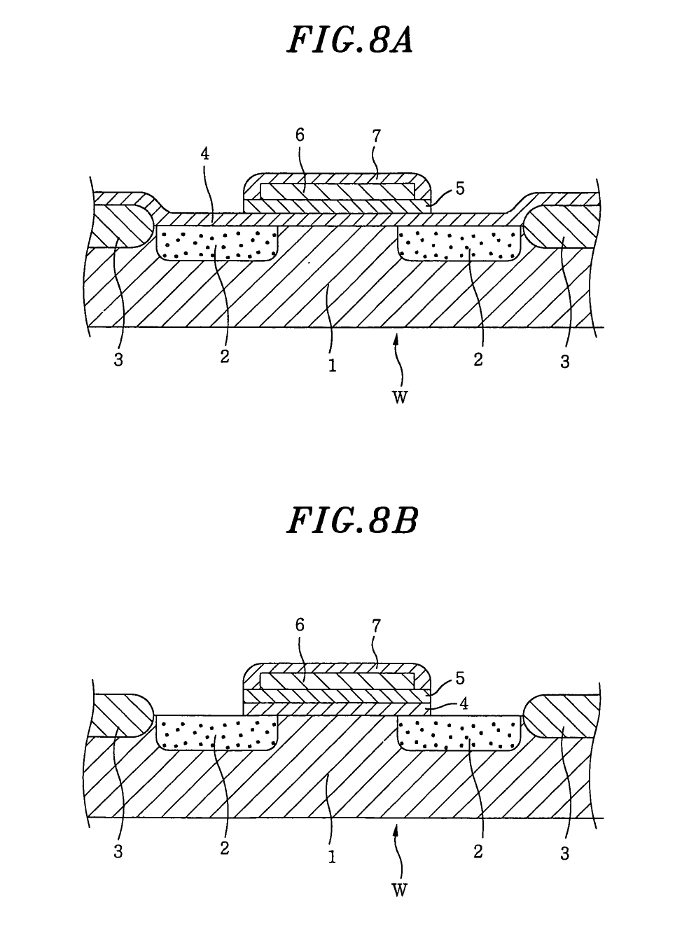

Hereinafter, a description will be given for the etching implemented in the etching apparatus 10 with reference to FIGS. 4 to 8B. FIG. 4 is a flow chart showing the etching steps conducted in the etching apparatus 10 in accordance with the first preferred embodiment, and FIGS. 5 and 6 schematically illustrate the etching performed in accordance with the first preferred embodiment. FIG. 7A illustrates a structural formula of Hhfac used in the first preferred embodiment, and FIG. 7B shows a structural formula of a Hf complex generated in the first preferred embodiment. FIG. 8A delineates a wafer W after a HfO₂ film 5 is etched away in accordance with the first preferred embodiment, and FIG. 8B describes a wafer W after a SiON film 4 is removed by etching in accordance with the first preferred embodiment.

First, by the operation of the depressurization pump 70, the inner chamber 40 is exhausted and vacuumized. Also, the depressurization pump 100 exhausts the space formed between the outer chamber 30 and the inner chamber 40 (step 1A).

Subsequently, the heating lamps 230 are turned on to heat the susceptor 120 (step 2A). Once a pressure in the inner chamber 40 is reduced to 9.31×10³-1.33×10⁴ Pa and a temperature of the susceptor 120 is elevated to reach 300° C. or higher, the gate valve 50 is opened and a transfer arm (not shown in the drawing), with a wafer W being mounted thereon, is extended to transfer the wafer W into the outer chamber 30 (step 3A).

Next, the transfer arm is pulled out leaving the wafer W therein to be supported by the wafer elevating pins 160. Once the wafer W is left on the wafer elevating pins 160, the air cylinder 180 operates to move the wafer elevating pins 160 downward, thereby placing the wafer W on the susceptor 120 to be loaded thereon (step 4A). Subsequent to the loading of the wafer W on the susceptor 120, the air cylinder 140 lifts the susceptor 120 in an upward direction to transfer the wafer W into the inner chamber 40 (step 5A).

Once the wafer W is heated and a temperature of the wafer W reaches 300° C. or higher, preferably 450° C. or higher, the opening/closing valves 280, 340, 370, 400 are opened and the Hhfac-containing etching gas is supplied from the nozzle 250 into the inner chamber 40 as shown in FIG. 5 (step 6A). The main components in the Hhfac-containing etching gas are Hhfac, O₂, H₂O and N₂. The flow rates of Hhfac, O₂ and N₂ are set at 320-380 sccm, 50-250 sccm and 100-300 sccm, respectively. H₂O is supplied into the inner chamber 40 with its concentration being about 2000 ppm or less (0 ppm inclusive). The Hhfac-containing etching gas supplied from the nozzle 250 flows along the surface of the wafer W in a laminar flow state. When the Hhfac-containing etching gas comes into contact with the HfO₂ film 5, Hhfac etches the HfO₂ film 5 through a reaction therewith while the SiO₂ film 7 is functioning as a mask. A reaction mechanism is as follows. Since Hhfac is a tautomeric material, Hhfac can exist in two forms, i.e., structure I and structure II as shown in FIG. 7A. In structure II, shared electrons between a C═O bond and a C—C bond become delocalized, thereby weakening an O—H bond. If the O—H bond is broken, Hhfac can coordinate with Hf from the HfO₂ film 5 to form a Hf complex as shown in FIG. 7B. The Hf complex so formed is vaporized and separated from a surface of the HfO₂ film 5. The reaction mechanism described so far shows how the HfO₂ film 5 is etched away with Hhfac. Once separated from the surface of the HfO₂ film 5, the Hf complex is exhausted from the outer chamber 30 through the gas exhaust line 60.

After the etching of the HfO₂ film 5 is conducted to expose a surface of the SiON film 4 as shown in FIG. 8A, the opening/closing valves 280, 340, 370 are closed and the supply of the Hhfac-containing etching gas is stopped. The heating lamps 230 are also turned off to stop the heating of the susceptor 120, thereby finishing the etching of the HfO₂ film 5. However, since the opening/closing valve 400 is still open, N₂ keeps flowing into the inner chamber 40 and cools down the wafer W (step 7A). Although the wafer W is shown to be cooled with N₂ in the first preferred embodiment, cooling can be achieved with any non-reactive gas and is not limited to N₂. The wafer W may also be cooled with a separate cooling device installed at the susceptor 120. The cooling device is, e.g., a peltier device or a water-cooled jacket.

After the wafer W is cooled and the temperature of the wafer W lowered to about 100° C. or less, preferably 10-50° C., the opening/closing valves 310, 370 are opened and the HF-containing etching gas is supplied from the nozzle 250 into the inner chamber 40 as shown in FIG. 6 (step 8A). The main components in the HF-containing etching gas are HF, H₂O and N₂. The HF-containing etching gas supplied from the nozzle 250 flows along the surface of the wafer W in a laminar flow state. When the HF-containing etching gas comes into contact with the SiON film 4, HF reacts therewith to etch the SiON film 4 while the SiO₂ film 7 functions as a mask.

The etching of the SiON film 4 is conducted until the surfaces of the P-type Si substrate 1 and SiO₂ film 3 are exposed as shown in FIG. 8B. Next, the opening/closing valves 310, 370, 400 are closed and the supply of the HF-containing etching gas is stopped (step 9A), thereby finishing the etching of the SiON film 4. After the stoppage of the supply of the HF-containing etching gas, the susceptor 120 moves downward by the operation of the air cylinder 140 and the wafer W is carried out of the inner chamber 40 (step 10A).

Subsequently, the wafer elevating pins 160 are raised by the operation of the air cylinder 180, whereby the wafer W is taken away from the susceptor 120 (step 11A). The gate valve 50 is opened and the transfer arm (not shown in the drawing) is extended to keep the wafer W thereon. Next, the transfer arm is retracted to carry the wafer W out of the outer chamber 30 (step 12A).

In the first preferred embodiment, since the Hhfac-containing etching gas is employed for the etching of the HfO₂ film 5 formed on the SiON film 4, damages to the SiO₂ film 3 can be reduced: for it is believed that a HF solution inflicts damages on the field oxide film due to a non-uniform etching rate in the uneven susceptibility of the film to the etching solution. Through the use of Hhfac having high etching selectivity, etching can be stopped once a SiON film 4 is exposed in etching the HfO₂ film 5 formed on the SiON film 4 in accordance with the first preferred embodiment. Accordingly, the differences in the etching between the part which is more amenable to the etching and the part which is less amenable can be reduced because the etching with the HF-containing etching gas is conducted on the SiON film 4 after the removal of the HfO₂ film 5. Therefore, damages to the SiO₂ film 3 can be mitigated.

In the first preferred embodiment, by the inclusion of O₂ and H₂O in the Hhfac-containing etching gas, the etching rate can be raised when etching the HfO₂ film 5. Furthermore, since the etching apparatus 10 is provided with the Hhfac supply source 270 and HF supply source 300, the HfO₂ film 5 and SiON film 4 can be etched in a single etching apparatus, thereby entailing a heightened throughput.

In the first preferred embodiment, since the Hhfac-containing etching gas and HF-containing etching gas are supplied to the wafer in such a way that they flow along a surface of the wafer W, the etching rate thereof can be improved.

In the first preferred embodiment, corrosion of the inner chamber 40 can be reduced since the materials fed thereinto are the Hhfac-containing etching gas and HF-containing etching gas. In contrast, if the HF solution was employed instead, it would be hard to remove the HF solution adhered to the chamber and the like therefrom. In the first preferred embodiment, since the Hhfac-containing etching gas, etc. is employed, cleaning can be done simply by exhausting the inner chamber 40 and the corrosion of the inner chamber 40 can be suppressed.

In the first preferred embodiment, the inner chamber 40 is made of quartz and the susceptor 120 is made of ceramics. However, the inner chamber 40 may also be made of SiC. The susceptor 120 and other members contacting the gas may also be made of, e.g., quartz, a PTFE (polytetrafluoro ethylene) coated metal, hastelloy or titanium. In such case, corrosion of the inner chamber 40 may be further suppressed.

### EXAMPLE 1; COMPARATIVE EXAMPLE 1

Hereinafter, a description will be given for Example 1 and Comparative Example 1. Subsequent to the etching of a HfO₂ film and an Al₂O₃ film formed on SiON films, their conditions were checked.

The test conditions were as follows. The etching apparatus of the first preferred embodiment was used to etch the HfO₂ film and the Al₂O₃ film formed on the wafers. The HfO₂ and Al₂O₃ films were formed on the wafers while the wafers were maintained at a temperature of about 300° C. The etching gas contained Hhfac and O₂, the respective flow rates thereof being 375 sccm and 100 scam. But H₂O was not included in the etching gas. The pressure in the inner chamber was about 1.13×10⁴ Pa. Such conditions were maintained during the etching of the HfO₂ and Al₂O₃ films.

For comparison, the conditions of HfO₂, Al₂O₃ and SiON films were checked in Comparative Example 1 after etching them with a HF solution.

Results were as follows. The HfO₂ and Al₂O₃ films formed on the SiON film were completely removed by etching them in both Example 1 and Comparative Example 1. Meantime, the SiON film in Comparative Example 1 underwent etching while that in Example 1 remained nearly intact.

From these observations, it can be ascertained that the etching of the SiON films can be prevented if the etching gas of Example 1 is employed when etching HfO₂ and Al₂O₃ films.

### EXAMPLE 2; REFERENCE EXAMPLE 2

Hereinafter, a description will be given for Example 2 and Reference Example 2. An optimum temperature of a wafer when etching a HfO₂ film was sought after.

The test conditions were as follows. The etching apparatus of the first preferred embodiment was used to etch the HfO₂ film formed on a wafer. The HfO₂ film was formed on the wafer while the wafer was maintained at a temperature of about 300° C. The etching gas contained Hhfac and O₂, the flow rates thereof being 375 scam and 100 sccm, respectively. But H₂O was not included in the etching gas. The pressure in the inner chamber was about 1.13×10⁴ Pa. While maintaining these conditions, the HfO₂ films were etched at various wafer temperatures.

As Reference Example 2, HfO₂ films formed at 150° C. were etched at various wafer temperatures. The HfO₂ film formed at 300° C. is known to be denser than that formed at 150° C.

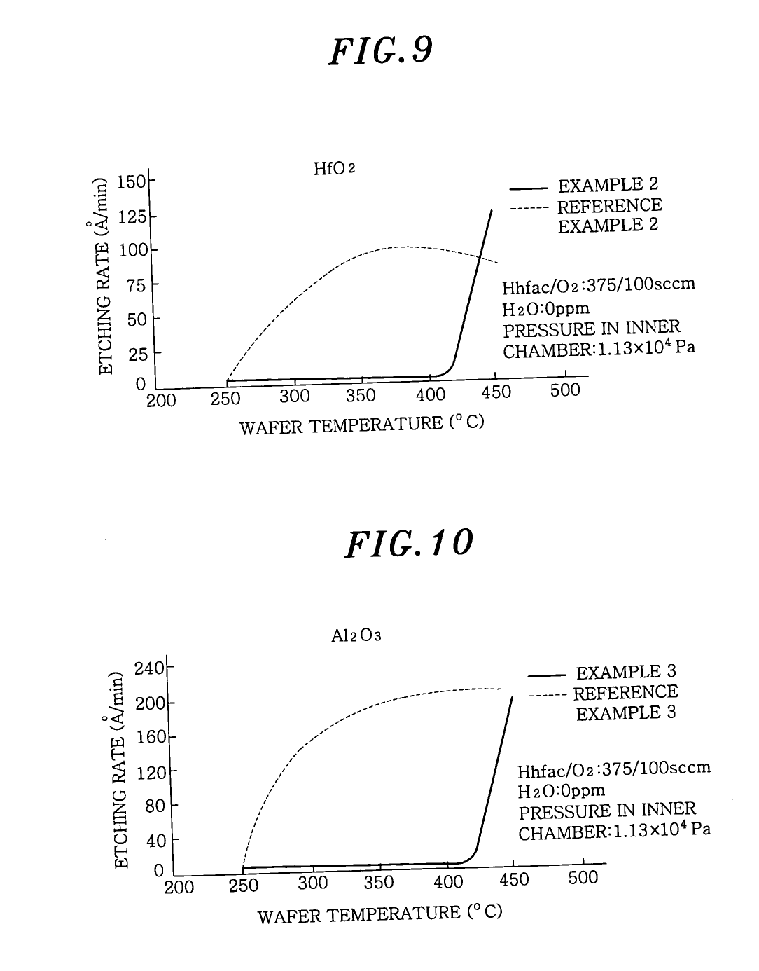

Results are summarized in FIG. 9 which shows the relationship between the etching rate of the HfO₂ film and the temperature of the wafer. As indicated in FIG. 9, the high etching rate was achieved when the temperature of the wafer was 400° C. or higher in etching the HfO₂ film in accordance with Example 2. Meanwhile, the high etching rate was achieved for Reference Example 2 when the temperature of the wafer was 350° C. or higher.

Based on the above, it is believed to be preferable to maintain the temperature of the wafer at 400° C. or higher when etching the HfO₂ film in accordance with Example 2. When etching the HfO₂ film in accordance with Reference Example 2, it is believed to be preferable to maintain the temperature of the wafer at 350° C. or higher.

### EXAMPLE 3; REFERENCE EXAMPLE 3

Hereinafter, a description will be given for Example 3 and Reference Example 3. An optimum temperature of a wafer when etching an Al₂O₃ film was sought after.

The test conditions were as follows. The etching apparatus of the first preferred embodiment was used to etch the Al₂O₃ film formed on the wafer. The Al₂O₃ film was formed on the wafer while the wafer was maintained at a temperature of about 300° C. The etching gas contained Hhfac and O₂, the flow rates thereof being 375 sccm and 100 sccm, respectively. But H₂O was not included in the etching gas. The pressure in the inner chamber was about 1.13×10⁴ Pa. While maintaining these conditions, the Al₂O₃ films were etched at various wafer temperatures.

As Reference Example 3, the Al₂O₃ film formed at 150° C. was etched at various wafer temperatures.

The results are summarized in FIG. 10 which shows the relationship between the etching rate of the Al₂O₃ film and the temperature of the wafer. As indicated in FIG. 10, a high etching rate was achieved when the temperature of the wafer was 400° C. or higher in etching the Al₂O₃ film in accordance with Example 3; meanwhile, a high etching rate was achieved in case of Reference Example 3 when the temperature of the wafer was 350° C. or higher.

Based on the above results, it is believed to be preferable to maintain the wafer at a temperature of 400° C. or higher when etching the Al₂O₃ film in accordance with Example 3. When etching the Al₂O₃ film in accordance with Reference Example 3, it is believed to be preferable to maintain the temperature of the wafer at 350° C. or higher.

### EXAMPLE 4; REFERENCE EXAMPLE 4

Hereinafter, a description will be given for Example 4 and Reference Example 4, wherein an optimum pressure in the inner chamber was sought after.

The test conditions were as follows. The etching apparatus of the first preferred embodiment was used to etch a HfO₂ film formed on a wafer. The HfO₂ film was formed on the wafer while the wafer was maintained at a temperature of about 300° C. The etching gas contained Hhfac and O₂, the flow rates thereof being 375 sccm and 100 sccm, respectively. But H₂O was not included in the etching gas. The etching temperature of the wafer was 450° C. While maintaining these conditions, the HfO₂ film was etched at various inner chamber pressures.

As Reference Example 4, the HfO₂ film formed at 150° C. was etched at various inner chamber pressures.

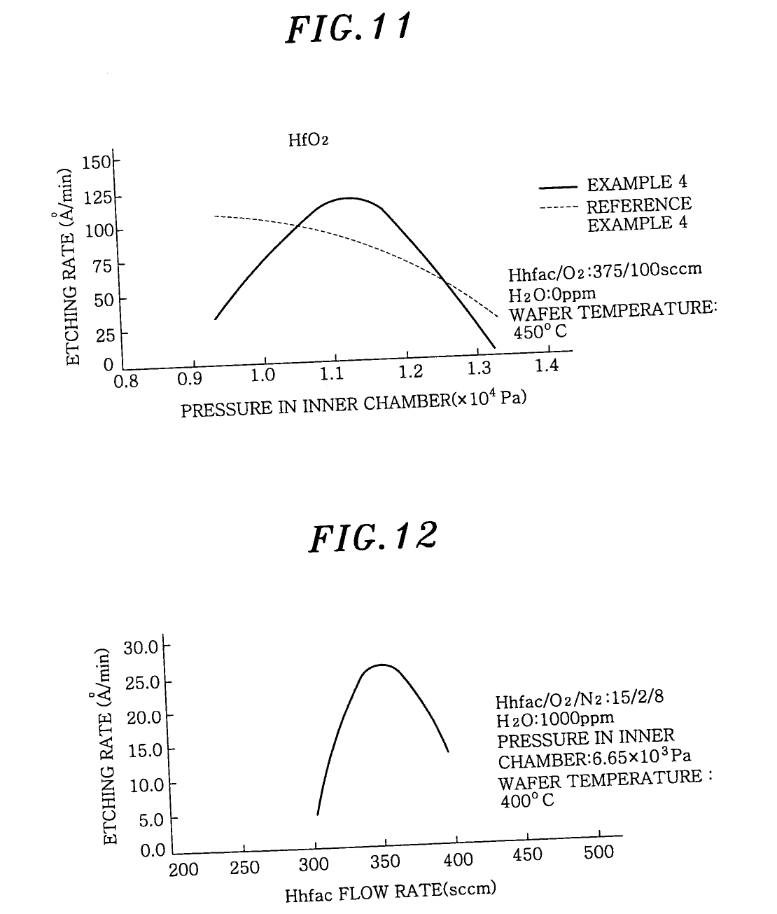

The results are summarized in FIG. 11 which shows the relationship between the etching rate of the HfO₂ film and the pressure in the inner chamber. As indicated in FIG. 11, the high etching rate was achieved when the pressure in the inner chamber was 1.06×10⁴-1.20×10⁴ Pa in etching the HfO₂ film in accordance with Example 4; meanwhile, the high etching rate was achieved for Reference Example 4 when the pressure in the inner chamber was 0.95×10⁴-1.20×10⁴ Pa.

Based on the above results, it is believed to be preferable to maintain the pressure in the inner chamber at 1.06×10⁴-1.20×10⁴ Pa when etching the HfO₂ film in accordance with Example 4. When etching the HfO₂ film in accordance with Reference Example 4, it is believed to be preferable to maintain the pressure in the inner chamber at 0.95×10⁴-1.20×10⁴ Pa.

### EXAMPLE 5

Hereinafter, a description will be given for Example 5, wherein an optimum flow rate of Hhfac was sought after.

The test conditions were as follows. The etching apparatus of the first preferred embodiment was used to etch a HfO₂ film formed on a wafer. The etching gas contained Hhfac and O₂, N₂ and H₂O. The ratios of Hhfac, O₂ and N₂ in the etching gas were 15:2:8 and the H₂O concentration therein was 1000 ppm. The pressure in the inner chamber was about 6.65×10³ Pa and the temperature of the wafer was about 400° C. While maintaining these conditions, the HfO₂ film was etched at various Hhfac flow rates.

The results are summarized in FIG. 12 which shows the relationship between the etching rate and the Hhfac flow rate. As indicated in FIG. 12, a high etching rate was achieved when the Hhfac flow rate was 320-380 sccm.

Based on the above results, it is believed to be preferable to maintain the Hhfac flow rate at 320-380 sccm when etching a HfO₂ film in accordance with Example 5.

### EXAMPLE 6; REFERENCE EXAMPLE 6

Hereinafter, a description will be given for Example 6 and Reference Example 6, wherein an optimum O₂ concentration when etching a HfO₂ film was sought after.

The test conditions were as follows. The etching apparatus of the first preferred embodiment was used to etch a HfO₂ film formed on a wafer. The HfO₂ film was formed on the wafer while the wafer was maintained at a temperature of about 300° C. The etching gas contained Hhfac, O₂ and H₂O. The flow rate of Hhfac was 375 sccm and the concentration of H₂O therein was 700 ppm. The pressure in the inner chamber was about 9.31×10³ Pa and the etching temperature of the wafer was about 450° C. While maintaining these conditions, the HfO₂ film was etched at various O₂ flow rates.

As Reference Example 6, HfO₂ film formed at 150° C. was etched at various O₂ flow rates.

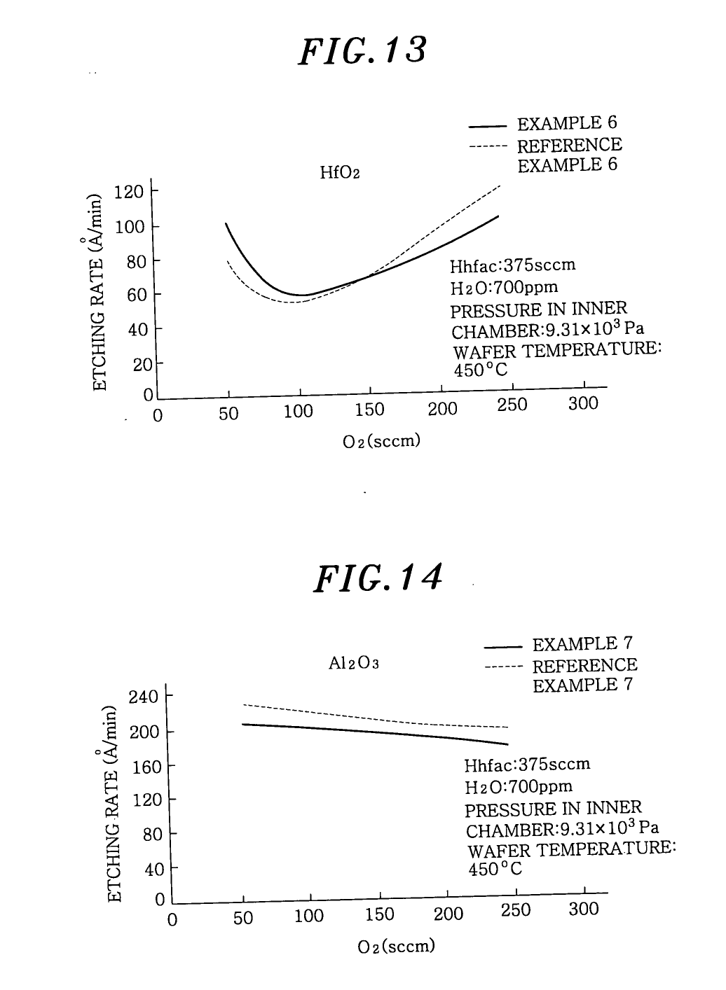

The results are summarized in FIG. 13 which shows the relationship between the etching rate of the HfO₂ film and the O₂ flow rate. As indicated in FIG. 13, a high etching rate was achieved when the O₂ flow rate was 50-250 sccm in etching the HfO₂ film in accordance with Example 6. Similar results were obtained in case the HfO₂ film was etched in accordance with Reference Example 6 (i.e., high etching rate was achieved when the O₂ flow rate was 50-250 sccm).

Based on the above results, it is believed to be preferable to maintain the O₂ flow rate at 50-250 scam when etching a HfO₂ film in accordance with Example 6 and Reference Example 6.

### EXAMPLE 7; REFERENCE EXAMPLE 7

Hereinafter, a description will be given for Example 7 and Reference Example 7, wherein an optimum O₂ concentration when etching an Al₂O₃ film was sought after.

The test conditions were as follows. The etching apparatus of the first preferred embodiment was used to etch an Al₂O₃ film formed on a wafer. The Al₂O₃ film was formed on the wafer while the wafer was maintained at a temperature of about 300° C. The etching gas contained Hhfac, O₂ and H₂O. The flow rate of Hhfac was 375 scam and the concentration of H₂O therein was 700 ppm. The pressure in the inner chamber was about 9.31×10³ Pa and the temperature of the wafer was about 450° C. While maintaining these conditions, the Al₂O₃ film was etched at various O₂ flow rates.

As Reference Example 7, Al₂O₃ film formed at 150° C. was etched at various O₂ flow rates.

The results are summarized in FIG. 14 which shows the relationship between the etching rate of the Al₂O₃ film and the O₂ flow rate. As indicated in FIG. 13, a high etching rate was achieved when the O₂ flow rate was maintained at a range of 50-250 scam in etching the Al₂O₃ film in accordance with Example 7. A similar result was obtained in case of Reference Example 7 (high etching rate was achieved when the O₂ flow rate was 50-250 sccm).

Based on the above results, it is believed to be preferable to maintain the O₂ flow rates at 50-250 sccm when etching the Al₂O₃ films in accordance with Example 7 and Reference Example 7.

### EXAMPLE 8; REFERENCE EXAMPLE 8

Hereinafter, a description will be given for Example 8 and Reference Example 8, wherein an optimum H₂O concentration when etching a HfO₂ film was sought after.

The test conditions were as follows. The etching apparatus of the first preferred embodiment was used to etch the HfO₂ film formed on a wafer. The HfO₂ film was formed on the wafer while the wafer was maintained at a temperature of about 300° C. The etching gas contained Hhfac, O₂ and H₂O. The flow rates of Hhfac and O₂ were 375 sccm and 50 sccm, respectively. The pressure in the inner chamber was about 9.31×10³ Pa and the temperature of the wafer was about 450° C. While maintaining these conditions, the HfO₂ film was etched at various H₂O concentrations.

As Reference Example 8, the HfO₂ film formed at 150° C. was etched at various H₂O concentrations.

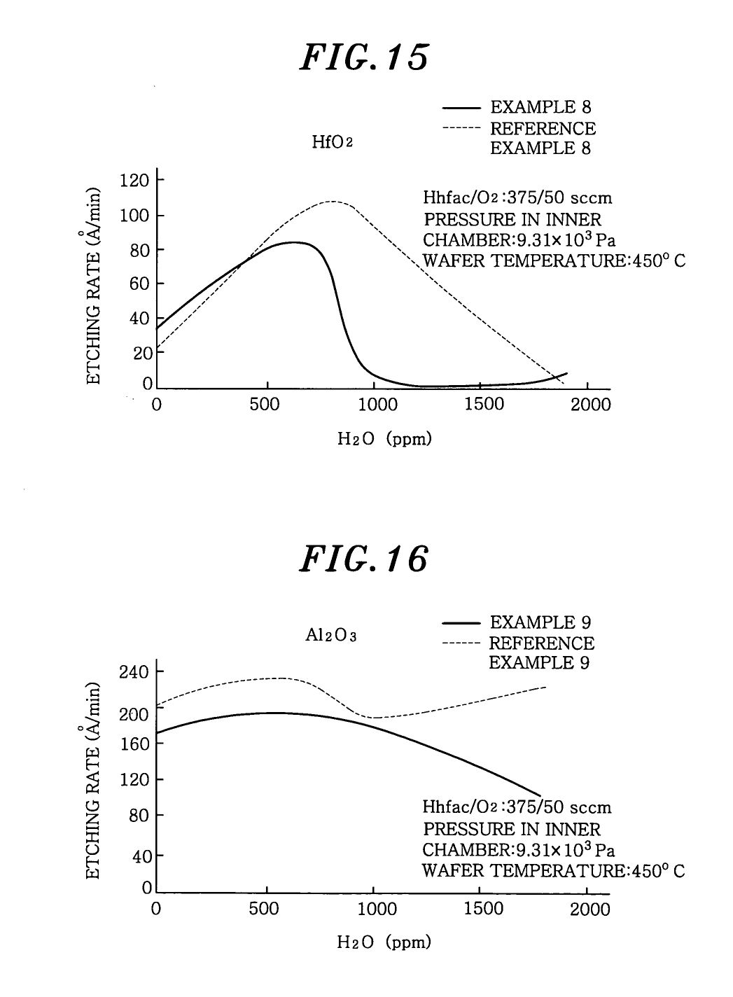

The results are summarized in FIG. 15 which shows the relationship between the etching rate of the HfO₂ film and the H₂O concentration. As indicated in FIG. 15, a high etching rate was achieved when the H₂O concentration was 1000 ppm or lower in etching the HfO₂ film in accordance with Example 8. A similar result was achieved in case of Reference Example 8 (i.e., the high etching rate was achieved when the H₂O concentration was 1000 ppm or lower). Furthermore, in both Reference Example 8 and Example 8, a high etching rate could be achieved even when H₂O was not included.

Based on the above results, it is believed to be preferable to maintain the H₂O concentration at 1000 ppm or less (0 ppm inclusive) when etching a HfO₂ film in accordance with Example 8 and Reference Example 8.

### EXAMPLE 9; REFERENCE EXAMPLE 9

Hereinafter, a description will be given for Example 9 and Reference Example 9, wherein an optimum H₂O concentration when etching an Al₂O₃ film was sought after.

The test conditions were as follows. The etching apparatus of the first preferred embodiment was used to etch an Al₂O₃ film formed on a wafer. The Al₂O₃ film was formed on the wafer while the wafer was maintained at a temperature of about 300° C. The etching gas contained Hhfac, O₂ and H₂O. The flow rates of Hhfac and O₂ were 375 sccm and 50 sccm, respectively. The pressure in the inner chamber was about 9.31×10³ Pa and the temperature of the wafer was about 450° C. While maintaining these conditions, the Al₂O₃ film was etched at various H₂O concentrations.

As Reference Example 9, an Al₂O₃ film formed at 150° C. was etched at various H₂O concentrations.

The results are summarized in FIG. 16 which shows the relationship between the etching rate of the Al₂O₃ film and the H₂O concentration. As indicated in FIG. 16, a high etching rate was achieved when the H₂O concentration was 1000 ppm or lower in etching the Al₂O₃ film in accordance with Example 9. A similar result was obtained in case of Reference Example 9 as well (i.e., high etching rate was achieved when the H₂O concentration was 1000 ppm or lower). In both Example 9 and Reference Example 9, high etching rate could be achieved even when H₂O was not included.

Based on the above results, it is believed to be preferable to maintain the H₂O concentration at 1000 ppm or less (0 ppm inclusive) when etching an Al₂O₃ film in accordance with Example 9 and Reference Example 9.

### EXAMPLE 10

Hereinafter, a description will be given for Example 10, wherein an optimum C₂H₅OH concentration was sought after.

The test conditions were as follows. The etching apparatus of the first preferred embodiment was used to etch a HfO₂ film formed on a wafer. The etching gas contained Hhfac, O₂, N₂ and C₂H₅OH. The flow rates of Hhfac, O₂ and N₂ were 375 scam, 50 scam and 200 scam, respectively. The pressure in the inner chamber was about 6.65×10³ Pa and the temperature of the wafer was about 400° C. While maintaining these conditions, the HfO₂ film was etched at various C₂H₅OH concentrations.

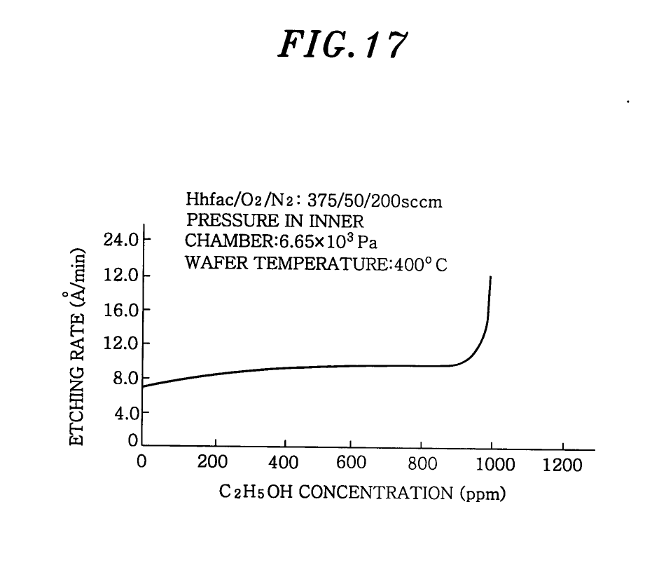

The results are summarized in FIG. 17 which shows the relationship between the etching rate of the HfO₂ film and the C₂H₅OH concentration. As indicated in FIG. 17, a high etching rate was achieved when the C₂H₅OH concentration was 500-1000 ppm.

Based on the above results, it is believed to be preferable to maintain the C₂H₅OH concentration at 500-1000 ppm when etching a HfO₂ film in accordance with Example 10.

### Second Preferred Embodiment

Hereinafter, a second preferred embodiment of the present invention will be explained. Some of the common expressions between the first and the following preferred embodiments will be omitted for the sake of simplicity. In the second preferred embodiment, explanations will be given on alternating the supply of a Hhfac-containing etching gas and a H₂O-containing gas; and alternating the supply of a HF-containing etching gas and a H₂O-containing gas.

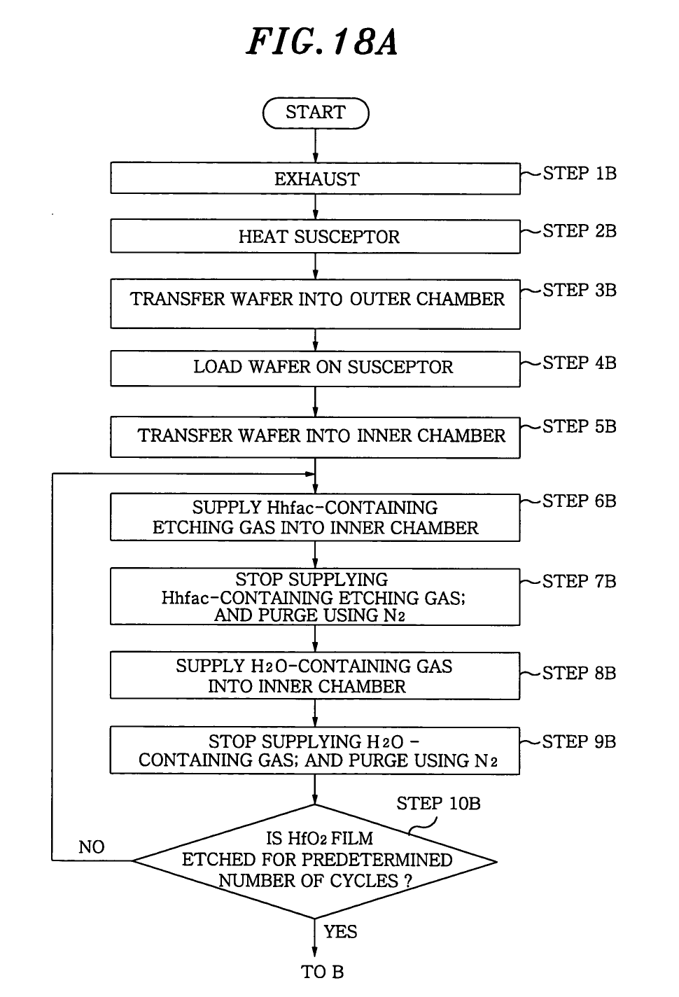

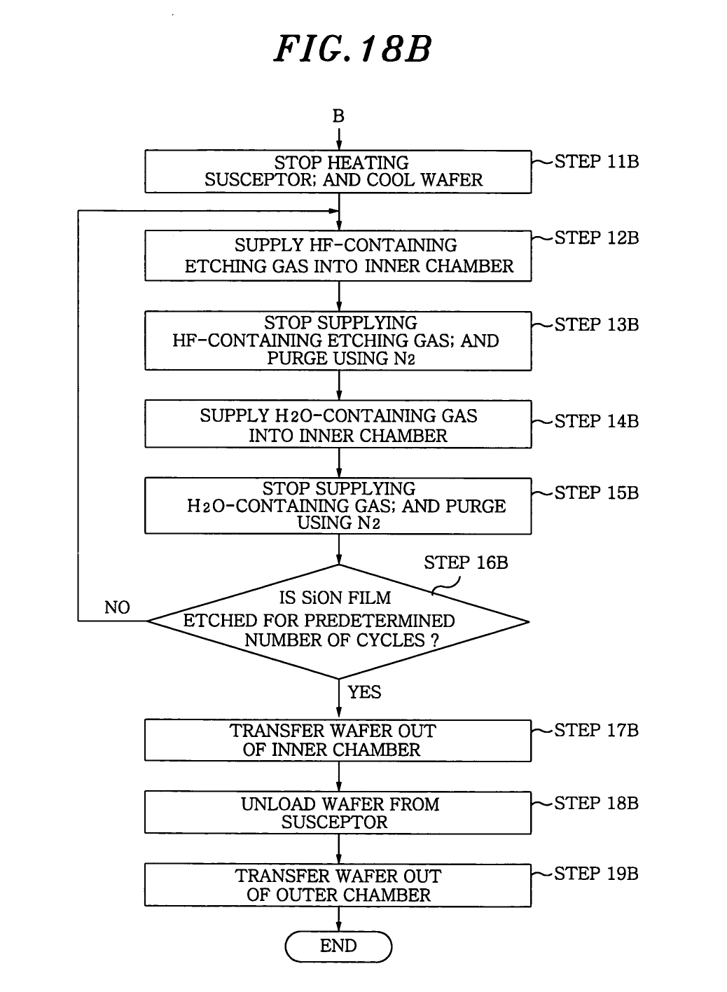

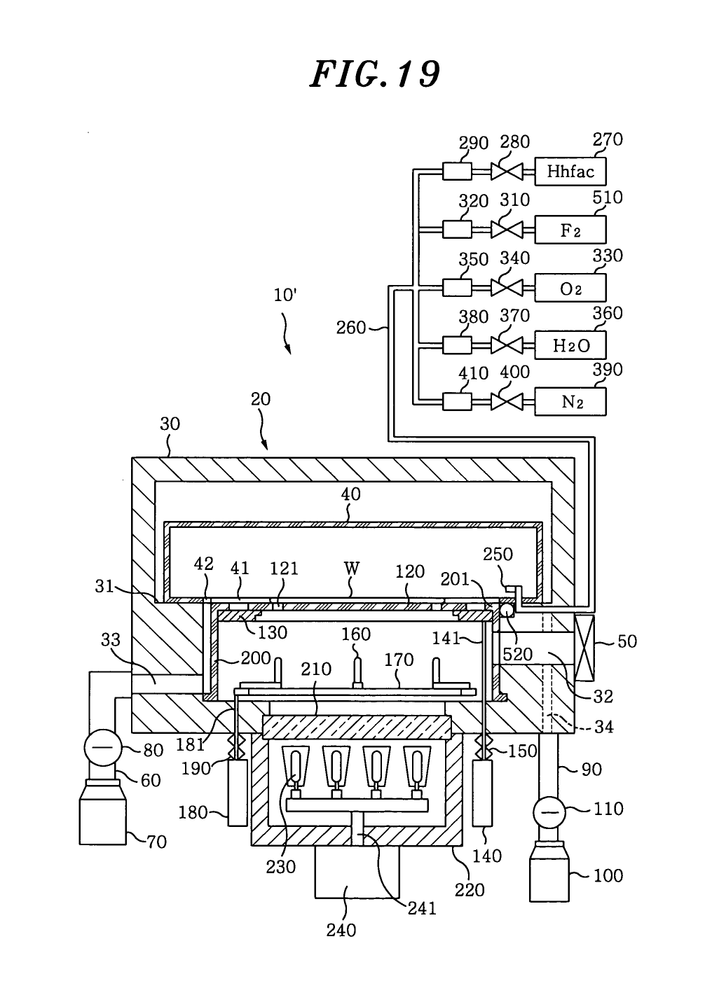

FIGS. 18A and 18B represent the flow charts showing the etching implemented in the etching apparatus 10 in accordance with the second preferred embodiment.

First, a depressurization pump 70 is operated to exhaust an inner chamber 40. And a depressurization pump 100 is operated as well to create a vacuum in a space formed between an outer chamber 30 and an inner chamber 40 (step 1B).

Next, heating lamps 230 are turned on to heat a susceptor 120 (step 2B). Once the pressure in the inner chamber 40 is reduced to 9.31×10³-1.33×10⁴ Pa and the temperature of the susceptor 120 is elevated to a certain level, a gate valve 50 is opened and a transfer arm (not shown in the drawing), with a wafer W being mounted thereon, is extended to transfer the wafer W into the outer chamber 30 (step 3B).

Next, the transfer arm is pulled out leaving the wafer W therein to be supported by the wafer elevating pins 160. Once the wafer W is left on the wafer elevating pins 160, an air cylinder 180 operates to move the wafer elevating pins 160 downward, thereby placing the wafer W on the susceptor 120 to be loaded thereon (step 4B). Subsequent to the loading of the wafer W on the susceptor 120, another air cylinder 140 lifts the susceptor 120 in an upward direction to transfer the wafer W into the inner chamber 40 (step 5B).

Once the wafer W is heated, the opening/closing valves 280, 340, 400 are opened and a Hhfac-containing etching gas is supplied (step 6B). The Hhfac-containing etching gas includes Hhfac, O₂ and N₂. When the Hhfac-containing etching gas comes into contact with a surface of a HfO₂ film 5, Hhfac is adsorbed onto the surface of the HfO₂ film 5. The remainder of the Hhfac-containing etching gas which remains unadsorbed on the surface of the HfO₂ film 5 is exhausted from the inner chamber 40.

After an elapse of a predetermined time, the valves 280, 340 are closed and the supply of the Hhfac-containing etching gas is stopped. However, since the valve 400 is still open, N₂ keeps flowing into the inner chamber 40, thereby purging the inner chamber 40. Accordingly, the remaining Hhfac except what has been adsorbed on the surface of the HfO₂ film 5 is exhausted from the inner chamber 40 (step 7B).

After an elapse of a predetermined time, an opening/closing valve 370 is opened and a H₂O-containing gas is supplied into the inner chamber 40 (step 8B). The H₂O-containing gas may include H₂O and N₂—Once the H₂O-containing gas reaches the surface of the HfO₂ film 5, a reaction between the HfO₂ film 5 and the portion of Hhfac adsorbed thereon is triggered and the HfO₂ film 5 is etched.

After an elapse of a predetermined time, the valve 370 is closed and the supply of the H₂O-containing gas is stopped, thereby ending the etching of the HfO₂ film 5. Since the valve 400 is still open, N₂ keeps flowing into the inner chamber 40 to purge the inner chamber 40 and exhaust the H₂O remaining therein (step 9B).

Next, a series of steps 6B to 9B is set as one cycle and a central controller (not shown in the drawing) determines whether or not to proceed to a next step based on the number of cycles (step 10B). If it is determined that a predetermined number has not been reached (i.e., the etching has not been conducted enough), the series of steps 6B to 9B will be repeated.

Once the etching of the HfO₂ film 5 is estimated to have been conducted for the predetermined number of cycles, the heating of the susceptor 120 is stopped. And N₂ is supplied into the inner chamber 40 for a certain duration to cool down the wafer W (step 11B). A surface of a SiON film 4 is in an exposed state when the HfO₂ film 5 is subject to etching for the predetermined number of cycles.

After the cooling of the wafer W, an opening/closing valve 310 is opened and a HF-containing etching gas is supplied into the inner chamber 40 (step 12B). Main components in the HF-containing etching gas are HF and N₂. When the HF-containing etching gas comes into contact with a surface of a SiON film 4, HF is adsorbed onto the surface of the SiON film 4. The HF-containing etching gas other than what has been adsorbed on the surface of the SiON film 4 is exhausted from the inner chamber 40.

After an elapse of a predetermined time, the valve 310 is closed and the supply of the HF-containing etching gas is stopped. However, since the valve 400 is still open, N₂ keeps flowing into the inner chamber 40, thereby purging the inner chamber 40. Accordingly, the remaining HF except what has been adsorbed on the surface of the SiON film 4 is exhausted from the inner chamber 40 (step 13B).

After an elapse of a predetermined time, the valve 370 is opened and a H₂O-containing gas is supplied into the inner chamber 40 (step 14B). Once the H₂O-containing gas reaches the surface of the SiON film 4, a reaction between the SiON film 4 and HF adsorbed thereon is triggered and the SiON film 4 is etched.

After an elapse of a predetermined time, the valve 370 is closed and the supply of the H₂O-containing gas is stopped, thereby ending the etching of the SiON film 4. Since the valve 400 is still open, N₂ keeps flowing into the inner chamber 40 to purge the inner chamber 40 and exhaust H₂O remaining therein (step 15B).

Next, a series of steps 12B to 15B is set as one cycle and a central controller (not shown in the drawing) determines whether or not to proceed to a next step based on the number of cycles (step 16B). If it is deemed that the predetermined number has not been reached (i.e., the etching has not been conducted enough), the series of steps 12B to 15B will be repeated.

If the etching of the SiON film 4 is estimated to have been conducted for a predetermined number of cycles, the susceptor 120 descends by the operation of an air cylinder 140 to transfer the wafer W out of the inner chamber 40 (step 17B). Surfaces of a P-type Si substrate 1 and a SiO₂ film 3 are in exposed states if the SiON film 4 was subjected to etching for a predetermined number of cycles.

Next, wafer elevating pins 160 move upwards by the operation of an air cylinder 180, whereby the wafer W is unloaded from the susceptor 120 (step 18B). Finally, a gate valve 50 is opened and the wafer W is carried out of the outer chamber 30 (step 19B).

In the second preferred embodiment, by alternating the supply of the Hhfac-containing etching gas and that of the H₂O-containing gas, the HfO₂ film 5 can be etched more accurately.

In addition, by alternating the supply of the HF-containing etching gas and that of the H₂O-containing gas, the SiON film 4 can be etched in a more accurate fashion.

### Third Preferred Embodiment

In accordance with a third preferred embodiment of the present invention, a SiON film will be etched using F radicals. FIG. 19 illustrates a schematic vertical sectional view of an etching apparatus employed in the third preferred embodiment.

As shown in FIG. 19, a gas supply line 260 is connected to a F₂ supply source 510 (containing F₂) instead of a HF supply source 300. A recess is formed near a nozzle 250 in an outer chamber 30 and a UV lamp 520 for emitting a UV light is provided therein. After the UV lamp 520 is turned on, the UV light generated from the UV lamp 520 is applied to the inner chamber 40 through the bottom thereof.

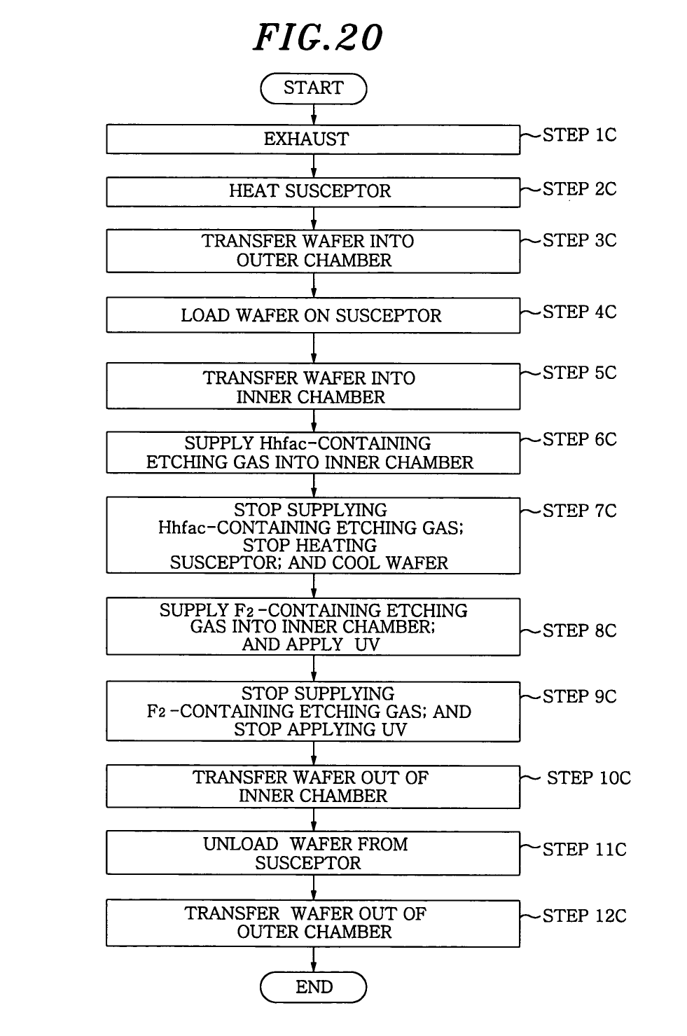

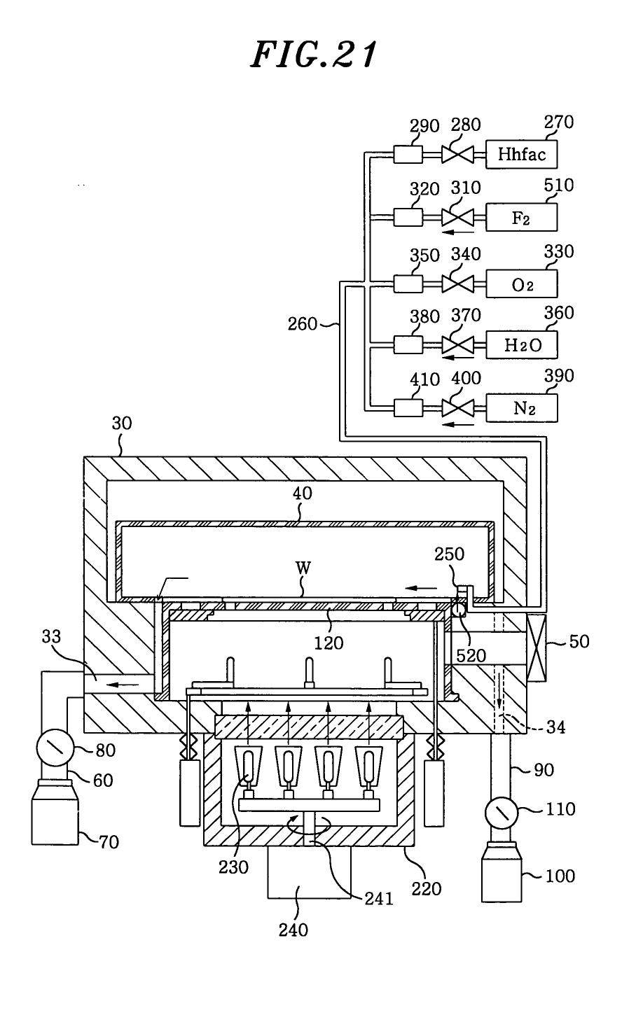

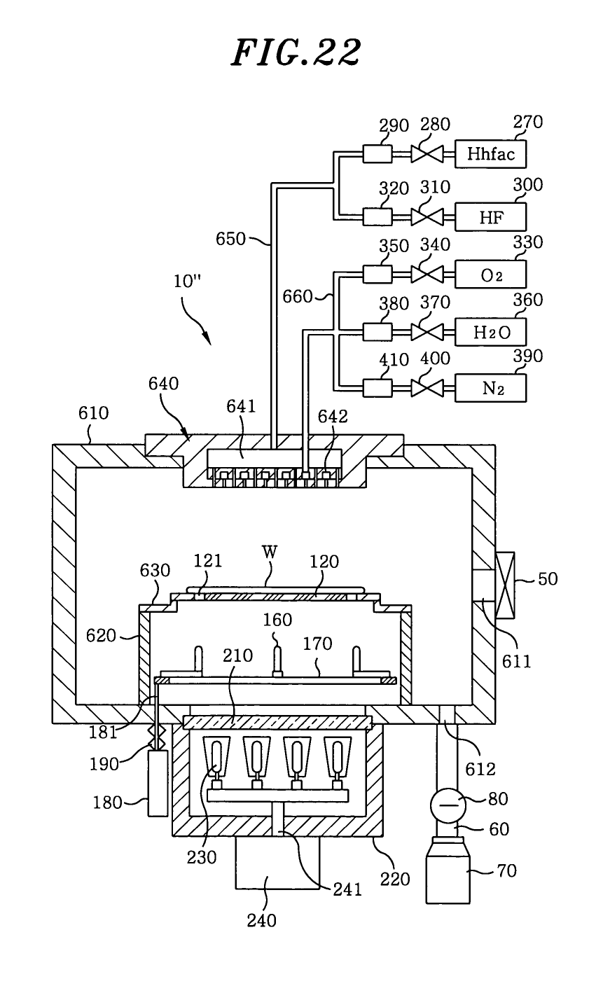

Hereinafter, a description will be given for the etching implemented in the etching apparatus 10′ with reference to FIGS. 20 and 21. FIG. 20 is a flow chart showing the etching implemented in the etching apparatus 10′ in accordance with the third preferred embodiment, and FIG. 21 illustrates a schematic view of the etching in accordance with the third preferred embodiment.

First, by the operation of the depressurization pump 70, the inner chamber 40 is exhausted and evacuated. Also, the depressurization pump 100 exhausts a space formed between the outer chamber 30 and the inner chamber 40 (step 1C).

Subsequently, the heating lamps 230 are turned on to heat the susceptor 120 (step 2C). Once the pressure in the inner chamber 40 is reduced to 9.31×10³-1.33×10⁴ Pa and the temperature of the susceptor 120 is elevated to reach 300° C. or higher, the gate valve 50 is opened and a transfer arm (not shown in the drawing), with a wafer W being mounted thereon, is extended to transfer the wafer W into the outer chamber 30 (step 3C).

Next, the transfer arm is pulled out leaving the wafer W therein to be supported by the wafer elevating pins 160. Once the wafer W is left on the wafer elevating pins 160, the air cylinder 180 operates to move the wafer elevating pins 160 downward, thereby placing the wafer W on the susceptor 120 to be loaded thereon (step 4C). Subsequent to the loading of the wafer W on the susceptor 120, the air cylinder 140 lifts the susceptor 120 in an upward direction to transfer the wafer W into the inner chamber 40 (step 5C).

After the wafer W is heated and the temperature of the wafer W reaches 300° C. or higher, preferably 450° C. or higher, the opening/closing valves 280, 340, 370, 400 are opened and a Hhfac-containing etching gas is supplied into the inner chamber 40 (step 6C), thereby initiating the etching of a HfO₂ film 5.

The etching of the HfO₂ film 5 is conducted and a surface of a SiON film 4 is exposed. Next, the valves 280, 340, 370 are closed while leaving the valve 400 in an opened state, whereby the supply of the Hhfac-containing etching gas is stopped. And the heating lamps 230 are turned off to stop the heating of the susceptor 120. This finishes the etching of the HfO₂ film 5. At the same time, the wafer W is cooled down by N₂ (step 7C).

After the wafer W is cooled and the temperature of the wafer W is stabilized at about 100° C. or less, preferably at 10-50° C., the opening/closing valves 310, 370 are opened and a F₂-containing etching gas is supplied into the inner chamber 40. The UV lamp 520 is turned on and the UV light is applied to the inner chamber 40 as shown in FIG. 21 (step 8C). The main components in the F₂-containing etching gas are F₂, N₂ and H₂O. When the F₂-containing etching gas is supplied into the inner chamber 40, F₂ is excited by UV light and F radicals are generated. The F radicals etch the SiON film 4 by reacting therewith.

The etching of the SiON film 4 is conducted until a surface of a P-type Si substrate 1 and a SiO₂ film 3 is exposed whereby the opening/closing valves 310, 370, 400 are closed to stop the supply of the F₂-containing etching gas. Furthermore, the UV lamp 520 is turned off and thus the generation of UV light is stopped (step 9C). This finishes the etching of the SiON film 4. After the supply of the F₂-containing etching gas is stopped, the susceptor 120 moves downward by the operation of the air cylinder 140 and the wafer W is carried out of the inner chamber 40 (step 10C).

Subsequently, the wafer elevating pins 160 move upward by the operation of the air cylinder 180 and the wafer W is unloaded from the susceptor 120 (step 11C). Finally, the gate valve 50 is opened and the wafer W is transferred out of the outer chamber 30 (step 12C).

### Fourth Preferred Embodiment

Hereinafter, a fourth preferred embodiment of the present invention will exemplify a showerhead for use in supplying a Hhfac-containing etching gas. FIG. 22 illustrates a schematic vertical sectional view of the etching apparatus in accordance with the fourth preferred embodiment.

As shown in FIG. 22, the etching apparatus 10″ is provided with a chamber 610 made of, e.g., Al. The chamber may be made of SiC, hastelloy or the like and is not limited to Al in its construction. An inside wall of the chamber 610 may be subject to a surface treatment such as an alumite treatment or a PTFE (polytetrafluoroethylene) coating. Openings 611, 612 are formed on predetermined positions of the chamber 610.

A gate valve 50 is attached to an outer end of the opening 611 and a gas exhaust line 60 is connected to an outer end of the opening 612. A cylindrical reflector 620 is provided in the chamber 610 to reflect light radiated from the heating lamps 230. The reflector 620 is made of, e.g., Al. A supporting member 630 is fixed to an upper part of the reflector 620 to support a susceptor 120, the supporting member 630 being made of, e.g., quartz.

The showerhead 640 is disposed on top of the chamber 610 in such a manner that the Hhfac-containing etching gas can be directed towards the susceptor 120. The showerhead 640 includes a gas feed unit 641 for supplying Hhfac and HF and a gas feed unit 642 for supplying O₂, H₂O and N₂. A plurality of gas supply holes are formed at the gas feed units 641, 642 to supply gases, such as Hhfac, therethrough.

A gas supply line 650 with a two-forked end is connected to the gas feed unit 641 and a gas supply line 660 with a three-forked end is connected to the gas feed unit 642. The gas supply line 650 is connected to a Hhfac supply source 270 and a HF supply source 300 while the gas supply line 660 is connected to an O₂ supply source 330, a H₂O supply source 360 and a N₂ supply source 390 with their forked ends.

### Fifth Preferred Embodiment

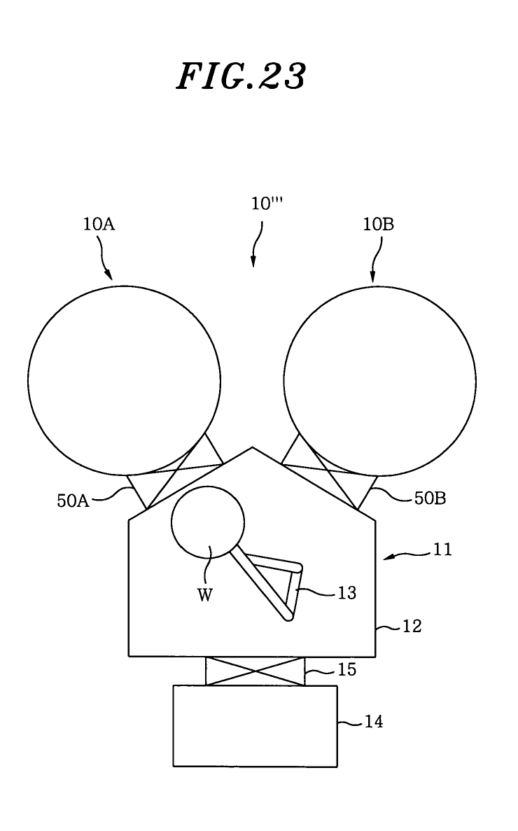

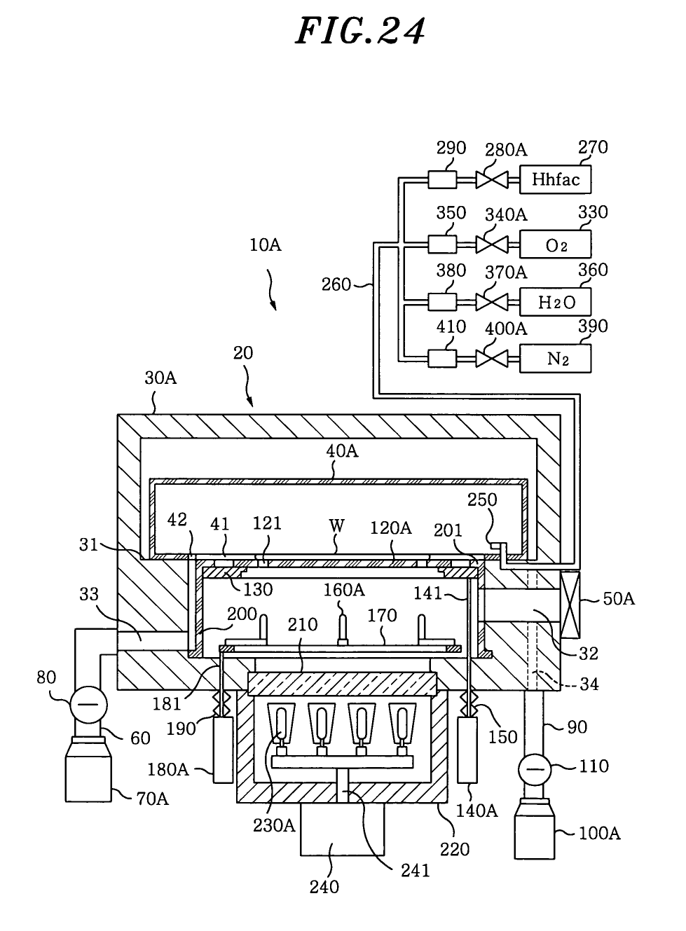

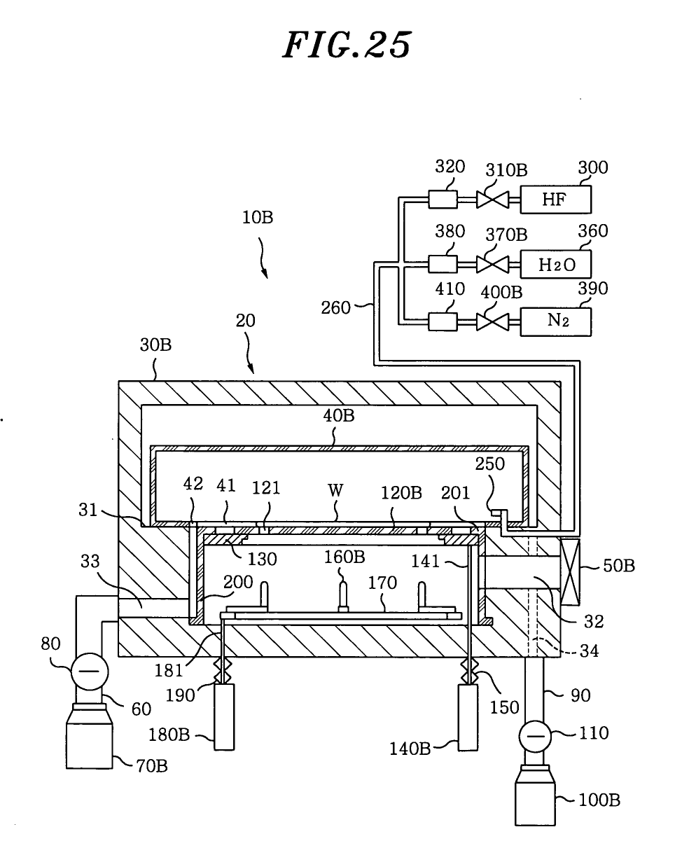

Hereinafter, a fifth preferred embodiment of the present invention will be explained for the employment of separate chambers in etching a HfO₂ film and a SiON film. FIG. 23 illustrates a schematic view of an etching apparatus in accordance with the fifth preferred embodiment. FIG. 24 shows a schematic vertical sectional view of a first etching part in accordance with the fifth preferred embodiment; and FIG. 25 illustrates a schematic vertical sectional view of a second etching part in accordance therewith.

As shown in FIGS. 23 to 25, main constituents of the etching apparatus 10″′ are the first etching part 10A for etching the HfO₂ film 5, the second etching part 10B for etching the SiON film 4 and a transfer system 11 for transferring a wafer W.

The structure of the first etching part 10A is almost identical to that of the etching apparatus 10 in FIG. 1. Only the HF supply source 300 is lacking in the first etching part 10A. Likewise, the second etching part 10B has almost the same structure as given in the etching apparatus 10 of FIG. 1. However, heating lamps 230, Hhfac supply source 270 and O₂ supply source 330 are not provided in the second etching part 10B.

The transfer system 11 is provided with a transfer chamber 12 which is connected to gate valves 50A, 50B. A transfer arm 13 is provided in the transfer chamber 12 to carry the wafer W into the first etching part 10A or its counterpart. The transfer chamber 12A is connected to a load-lock chamber 14 via a gate valve 15, the load-lock chamber 14 being used to receive a carrier cassette storing about 25 wafers W therein.

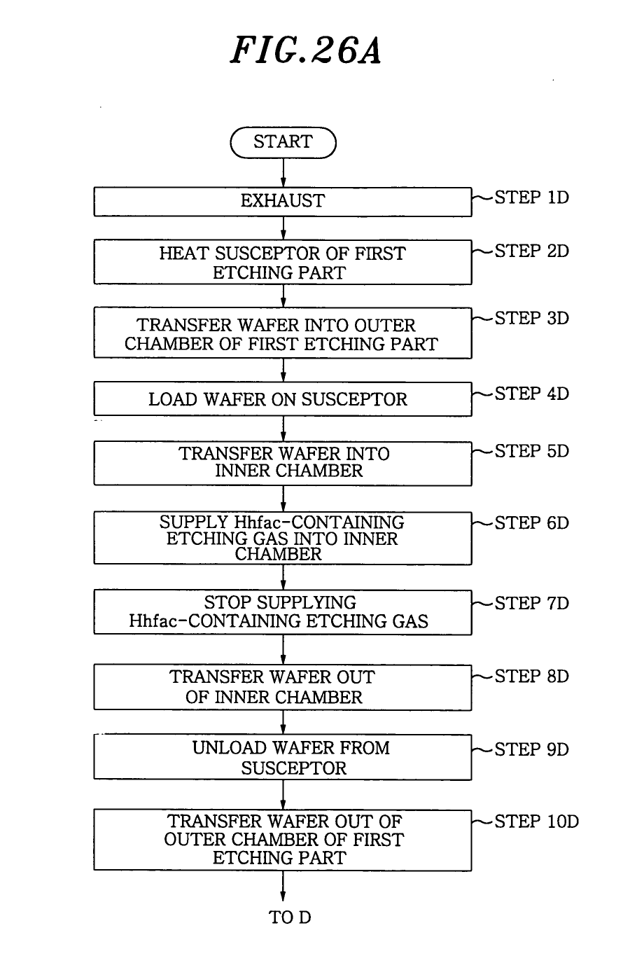

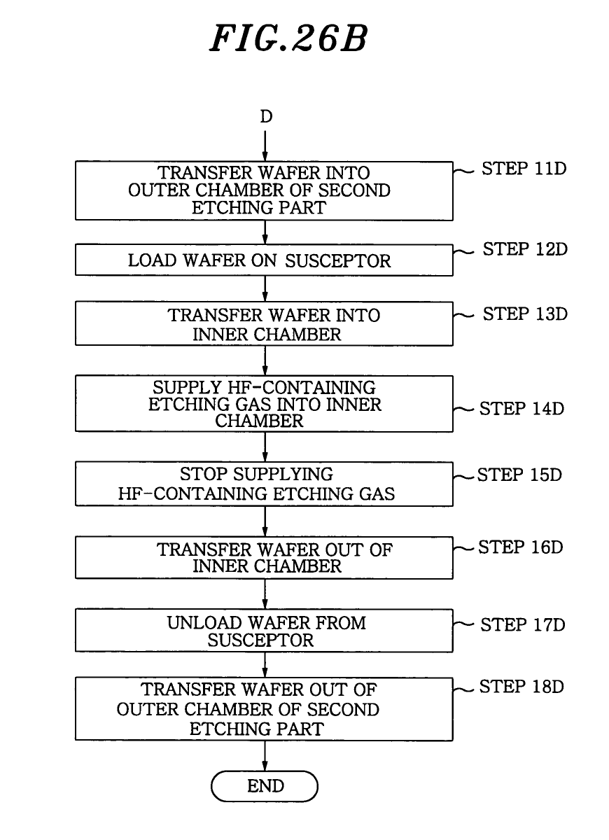

Hereinafter, a description will be given for the etching implemented in the etching apparatus 10″′ with reference to FIGS. 26A and 26B. FIGS. 26A and 26B are flow charts showing the etching implemented in the etching apparatus 10″′ in accordance with the fifth preferred embodiment.

First, depressurization pumps 70A, 70B are operated to exhaust inner chambers 40A, 40B. And depressurization pumps 100A, 100B are operated as well to evacuate: a space formed between an outer chamber 30A and the inner chamber 40A; and a space formed between an outer chamber 30B and the inner chamber 40B (step 1D).

Subsequently, heating lamps 230A are turned on to heat a susceptor 120A (step 2D). Once the pressures in both inner chambers 40A, 40B are reduced to 9.31×10³-1.33×10⁴ Pa and the temperature of the susceptor 120A is elevated to reach 300° C. or higher, a gate valve 15 is opened and the transfer arm 13 takes the wafer W out of the carrier cassette placed in the load-lock chamber 14. Next, the gate valve 50A is opened and the transfer arm 13 is extended therein to transfer the wafer W into the outer chamber 30A (step 3D).

Thereafter, the transfer arm 13 is pulled out leaving the wafer W therein to be supported by the wafer elevating pins 160A. Once the wafer W is left on the wafer elevating pins 160A, an air cylinder 180A operates to move the wafer elevating pins 160A downward, thereby placing the wafer W on the susceptor 120A to be loaded thereon (step 4D). Subsequent to the loading of the wafer W on the susceptor 120A, the air cylinder 140A lifts the susceptor 120A in an upward direction to transfer the wafer W into the inner chamber 40A (step 5D).

Once the wafer W is heated and the temperature of the wafer W reaches 300° C. or higher, preferably 450° C. or higher, the opening/closing valves 280A, 340A, 370A, 400A are opened and the Hhfac-containing etching gas is supplied into the inner chamber 40A (step 6D), thereby initiating the etching of a HfO₂ film 5.

The etching of the HfO₂ film 5 is conducted and a surface of a SiON film 4 is exposed. Next, the valves 280A, 340A, 370A and 400A are closed to stop the supply of the Hhfac-containing etching gas. (step 7D). This finishes the etching of the HfO₂ film 5.

After the stoppage of the supply of the Hhfac-containing etching gas, the susceptor 120A moves downward by the operation of the air cylinder 140A and the wafer W is transferred out of the inner chamber 40A (step 8D).

Subsequently, the wafer elevating pins 160A move upward by the operation of the air cylinder 180A and the wafer W is unloaded from the susceptor 120A (step 9D). Finally, the gate valve 50A is opened and the wafer W is transferred out of the outer chamber 30A (step 10D).

Thereafter, the gate valve 50B is opened and the transfer arm 13 extends to feed the wafer W into the outer chamber 30B (step 11D).

Next, the transfer arm 13 is pulled out leaving the wafer W therein to be supported by the wafer elevating pins 160B. Once the wafer W is left on the wafer elevating pins 160B, an air cylinder 180B operates to move the wafer elevating pins 160B downward, thereby placing the wafer W on the susceptor 120B to be loaded thereon (step 12D). Subsequent to the loading of the wafer W on the susceptor 120B, another air cylinder 140B lifts the susceptor 120B in an upward direction to transfer the wafer W into the inner chamber 40B (step 13D).

After the wafer W is transferred into the inner chamber 40B, opening/closing valves 310B, 370B, 400B are opened and a HF-containing etching gas is supplied into the inner chamber 40 (step 14D), thereby initiating the etching of a SiON film 4.

After the etching of the SiON film 4 is conducted to expose surfaces of a P-type Si substrate 1 and a SiO₂ film 3, the opening/closing valves 310B, 370B, 400B are closed and the supply of the HF-containing etching gas is stopped (step 15D). This finishes the etching of the SiON film 4.

After the supply of the HF-containing etching gas is stopped, the susceptor 120B descends by the operation of the air cylinder 140B and the wafer W is carried out of the inner chamber 40B (step 16D). Subsequently, the wafer elevating pins 160B move upward by the operation of the air cylinder 180B and the wafer W is unloaded from the susceptor 120B (step 17D).

Once the wafer W is unloaded from the susceptor 120B, the gate valve SOB is opened and the transfer arm 13 takes the wafer W out of the outer chamber 30B (step 18D).

The present invention has been described in an illustrative manner and it is to be understood by those skilled in the art that various changes and modifications may be made without departing from the spirit and scope of the present invention. Proper modifications of structures, materials and arrangements of members in accordance with the present invention are possible. In the first to fifth preferred embodiments, a Hhfac-etching (etching with the Hhfac-containing etching gas) is conducted on the HfO₂ film 5. However, a metal film may be a subject of the Hhfac-etching as well. Examples of the metal film may include Al, Zr, Hf, Y, La, Ce and Pr. Furthermore, a glass substrate may be used instead of the wafer W.

The first, second, fourth and fifth preferred embodiments employ a HF-containing etching gas. However, an etching solution, such as a HF solution, may be used in place of the HF-containing etching gas.

In the first, third, fourth and fifth preferred embodiments, the main components in the Hhfac-containing etching gas are Hhfac, O₂, H₂O and N₂ and those in the second preferred embodiment are Hhfac, O₂ and N₂. However, components other than Hhfac may be removed from the Hhfac-containing etching gas.

In the first, fourth and fifth preferred embodiments, main components in the HF-containing etching gas are HF, H₂O and N₂ and those in the second preferred embodiment are HF and N₂. However, components other than HF may be removed from the HF-containing etching gas. Additionally, even though the main components in the F₂-containing etching gas of the third preferred embodiment are F₂, H₂O and N₂, components other than F₂ may be removed from the F₂-containing etching gas.

### Industrial Applicability

It is possible to apply the etching method and the etching apparatus in accordance with the present invention to the semiconductor fabrication industry.

1. An etching method, comprising the steps of:
providing a substrate on which a thin film is formed; and
etching, without generating a plasma, the thin film formed on the substrate with an etching gas containing a β-diketone and a gas containing water and/or alcohol to expose a surface of the substrate.

2. The etching method of claim 1, wherein the β-diketone is hexafluoro acetyl acetone.

3. The etching method of claim 1, wherein the etching gas containing a β-diketone includes the gas containing water and/or alcohol.

4. The etching method of claim 1, wherein the etching is conducted by alternating the supply of the etching gas containing a β-diketone and the gas containing water and/or alcohol.

5. The etching method of claim 1, wherein the etching is conducted at a temperature of 300° C. or higher.

6. The etching method of claim 5, wherein the etching is conducted at a temperature of 450° C. or higher.

7. The etching method of claim 1, wherein the etching gas containing a β-diketone is supplied in such a manner that the etching gas containing a β-diketone flows along a surface of the thin film.

8. The etching method of claim 1, wherein the thin film includes a metal film and/or a metal oxide film.

9. The etching method of claim 8, wherein the metal film and/or the metal oxide film includes at least one element selected from the group consisting of Al, Zr, Hf, Y, La, Ce and Pr.

10. The etching method of claim 8, wherein the surface of the substrate is made of a Si-containing film.

11. The etching method of claim 10, further comprising the step of etching the Si-containing film.

12. The etching method of claim 11, wherein the Si-containing film is etched with an etching gas including a fluorine-containing gas or with an etching solution including a hydrogen fluoride solution.

13. The etching method of claim 12, wherein the etching gas including a fluorine-containing gas contains water and/or alcohol.

14. The etching method of claim 12, wherein the etching of the Si-containing film is conducted by alternating the supply of the etching gas including a fluorine-containing gas and a gas including water and/or alcohol.

15. The etching method of claim 11, wherein the etching of the Si-containing film is conducted while the substrate is maintained at a temperature of 100° C. or less.

16. An etching apparatus, comprising:
a reactor for accommodating a substrate on which a first thin film and a second thin film are formed, the second thin film being disposed under the first thin film;
a first supply system for feeding a first etching gas containing a β-diketone into the reactor to etch the first thin film; and
a second supply system for feeding a second etching gas including a fluorine-containing gas, or an etching solution including a hydrogen fluoride solution into the reactor to etch the second thin film.

17. The etching apparatus of claim 16, wherein the β-diketone is hexafluoro acetyl acetone.

18. An etching apparatus, comprising:
a first reactor for accommodating a substrate on which a first thin film and a second thin film are formed, the second thin film being disposed under the first thin film;
a first supply system for feeding a first etching gas containing a β-diketone into the first reactor to etch the first thin film;
a second reactor for accommodating the substrate after the first thin film is removed by etching;
a second supply system for feeding a second etching gas including a fluorine-containing gas, or an etching solution including a hydrogen fluoride solution into the second reactor to etch the second thin film; and
a substrate transfer mechanism for transferring the substrate into the first and second reactors.

19. The etching apparatus of claim 18, wherein the β-diketone is hexafluoro acetyl acetone.
